(19) United States
(12) Patent Application Publication
(10) Pub. No.: US 2025/0218963 A1
(43) Pub. Date: Jul. 3, 2025

(54) DIE AND CONDUCTIVE VIAS EMBEDDED IN A SUBSTRATE

(71) Applicant: Intel Corporation, Santa Clara, CA (US)

(72) Inventors: Hiroki Tanaka, Gilbert, AZ (US); Robert May, Chandler, AZ (US); Bai Nie, Chandler, AZ (US); Srinivas Pietambaram, Chandler, AZ (US); Bohan Shan, Chandler, AZ (US); Gang Duan, Chandler, AZ (US); Benjamin Duong, Phoenix, AZ (US); Tolga Acikalin, San Jose, CA (US); Soham Agarwal, Chandler, AZ (US); Jeremy Ecton, Gilbert, AZ (US); Kari Hernandez, Phoenix, AZ (US); Brandon Marin, Gilbert, AZ (US); Pratyush Mishra, Tempe, AZ (US); Pratyasha Mohapatra, Hillsboro, OR (US); Marcel Said, Beaverton, OR (US)

(73) Assignee: Intel Corporation, Santa Clara, CA (US)

(21) Appl. No.: 18/399,383

(22) Filed: Dec. 28, 2023

(51) Int. Cl. H01L 23/538; H01L 21/48; H01L 23/00; H01L 23/15; H01L 23/28; H01L 23/64

(52) U.S. Cl. CPC H01L 23/5386; H01L 21/4857; H01L 23/15; H01L 23/28; H01L 23/5384; H01L 23/642; H01L 24/16; H01L 2224/16227

(57) ABSTRACT

An apparatus includes a substrate core, which has a first height between a first surface and a second surface opposite the first surface. A die is within the substrate core. The die may include a deep trench capacitor. The die has a second height between a first side of the die and a second side opposite the first side. The first height is greater than the second height. A plurality of conductive vias extend from a plurality of conductive contacts at the first side of the die to the first surface of the substrate core. A material comprising a dielectric is disposed over the die and encapsulates the plurality of conductive vias. In some embodiments, a bond film is in contact with the second side of the die.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

In addition to IC chips, some IC packages architectures include capacitors or other discrete components on a surface of a package substrate. These components may be used, for example, in voltage regulation circuitry. However, the space available on the surface is limited. Including a discrete component on a surface of a package substrate of a particular size may reduce the number of IC chips that can assembled in an IC chip package. Alternatively, the size of the package substrate may need to be increased to accommodate a desired number of IC chips.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate a flow diagram of methods for forming an IC device package including a die within and near a back side of a substrate core, and conductive vias extending from a front side of the die to a surface of the substrate core, wherein the height of the die is less than the height of the substrate core, in accordance with some embodiments;

FIGS. 2A through 2R illustrate cross-sectional views of a substrate core evolving to include a die within and near a back side of the substrate core, and conductive vias extending from a front side of the die to a surface of the substrate core, wherein the height of the die is less than the height of the substrate core as selected operations in the methods illustrated in FIGS. 1A and 1B are performed, in accordance with some embodiments;

FIG. 3 illustrates a cross-sectional view of a die comprising a deep trench capacitor, according to an example;

FIGS. 4A through 4C illustrate cross-sectional views a substrate, which includes a substrate core the same as or similar to the substrate core of FIG. 2R evolving to a device package structure as selected operations in the methods illustrated in FIGS. 1A and 1B are performed, in accordance with some embodiments;

FIG. 4D illustrates a cross-sectional view of the device package structure of FIG. 4C evolving to a system including the device package structure as selected operations in the methods illustrated in FIGS. 1A and 1B are performed, in accordance with some embodiments;

FIG. 5 illustrates a flow diagram of methods for forming an IC device package including a die within and near a back side of a substrate core, and conductive vias extending from a front side of the die to a surface of the substrate core, wherein the height of the die is less than the height of the substrate core, in accordance with some embodiments;

FIGS. 6A through 6G illustrate cross-sectional views of a substrate core evolving to include a die within and near a back side of the substrate core, and conductive vias extending from a front side of the die to a surface of the substrate core, wherein the height of the die is less than the height of the substrate core as selected operations in the methods illustrated in FIG. 5 are performed, in accordance with some embodiments;

FIGS. 7A through 7C illustrate cross-sectional views a substrate, which includes a substrate core the same as or similar to the substrate core of FIG. 6G evolving to a device package structure as selected operations in the methods illustrated in FIG. 5 are performed, in accordance with some embodiments;

FIG. 7D illustrates a cross-sectional view of the device package structure of FIG. 7C evolving to a system including the device package structure as selected operations in the methods illustrated in FIG. 5 are performed, in accordance with some embodiments;

FIG. 8 illustrates a mobile computing platform and a data server machine employing one or more of IC device package structures illustrated in FIG. 4C and/or FIG. 7C, and/or one or more of the systems illustrated in FIG. 4D and/or FIG. 7D, in accordance with some embodiments; and

FIG. 9 is a functional block diagram of an electronic computing device employing one or more of IC device package structures illustrated in FIG. 4C and/or FIG. 7C, and/or one or more of the systems illustrated in FIG. 4D and/or FIG. 7D, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Integrated circuit (IC) device package structures that include a substrate core and a die within the substrate core are described herein. The die can include a deep trench capacitor (DTC) or other discrete component, and be prefabricated in a process separate from the process employed to fabricate the device package. For example, the die can be prefabricated from a silicon wafer. The substrate core may be thicker than the thickness of the die. It can be desirable to have a relatively thick substrate core for a variety of reasons. The substrate core may be thicker than the die because the thickness of the die may be limited wafer thickness in the separate manufacturing process.

The die may be placed in an opening in substrate core. When the substrate core is thicker than the die, it can be challenging to align the die in a desired x-y-z position, and to keep the die properly aligned during manufacturing operations, like dielectric encapsulation. For example, the die may rotate, shift, or tilt during encapsulation. Furthermore, when an improperly aligned die is encapsulated with a dielectric material, there may be undesirable variations in the thickness of the material. In addition, die misalignment can reduce the yield of successfully fabricated device packages.

Embodiments are directed to an apparatus having a substrate core and a die within the substrate core. The substrate core may include a first surface and a second surface opposite the first surface. The substrate core has a first height. The die includes a first side and second side opposite the first side. The die has a second height. The first height is greater than the second height by a height difference. Conductive vias extend from conductive contacts at the first side of the die to the first surface of the substrate core. The die may be nearer to the second surface than the first surface such that the conductive vias span a distance that is at least eighty to ninety-five percent of the height difference. The second side of the die may be at or near to the second surface of the substrate core. A distance between the second side of the die to the second surface may be less than five to twenty percent of the height difference.

Embodiments are directed to an apparatus having a substrate core and a die having a DTC within the substrate core. Embodiments may include a dielectric material over the die that encapsulates the plurality of conductive vias. In some embodiments, the dielectric material is between a sidewall of the die and an interior surface of the substrate core. In some embodiments, the dielectric material has a side that is substantially coplanar with the second surface of the substrate core. The second side of the die may be substantially coplanar with the second surface of the substrate core

In some embodiments, the second side of the die may be spaced away from a plane of the second surface of the substrate core, and a bond film may be in contact with the second side of the die. A layer of dielectric material may be provided over the second surface of the substrate core. The bond film may be between the second side of the die and the layer of dielectric material.

Embodiments are directed to a substrate core that includes a hole in the core for placement of a die. Methods for forming an IC device package including forming the hole, placing the die within the hole, depositing a dielectric material in the hole and over the die, and forming through-dielectric vias connected with conductive contacts on the die.

Advantageously, the IC device package structures described herein permit a die that is thinner than a substrate core to be properly aligned and fixed in a desired x-y-z position within a hole in the substrate. In comparison with some prior methods, a further advantage of the embodiments described herein is that rotating, shifting, and tilting of the die during a dielectric encapsulation process may be reduced or substantially eliminated. Another advantage of various embodiments is that variations in the thickness of the dielectric material encapsulating a die may be less than the thickness variations of some known methods. Some, but not all, embodiments advantageously permit die placement within a hole in the substrate core without requiring the use of a sacrificial panel. Further, the embodiments described herein may advantageously result in improved manufacturing yields.

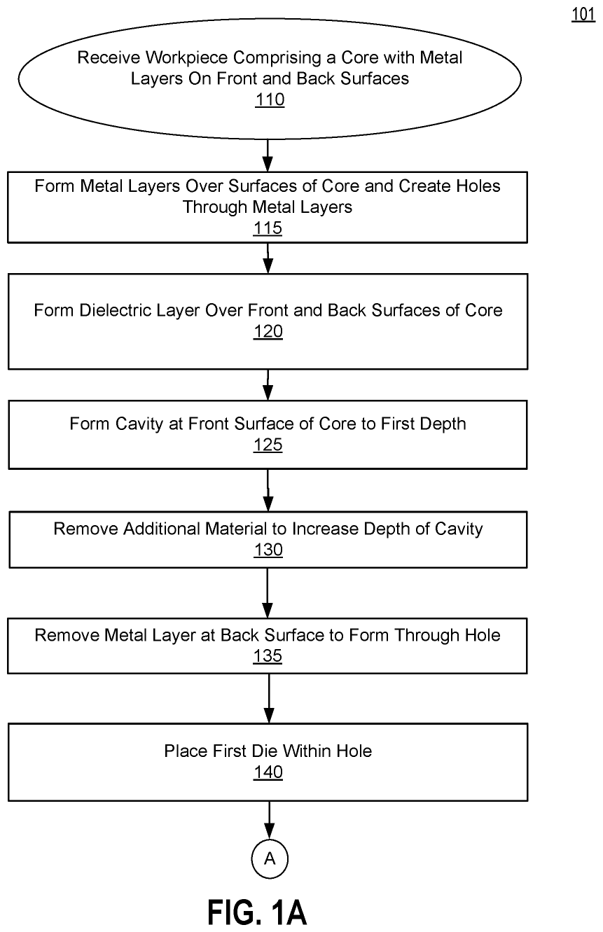

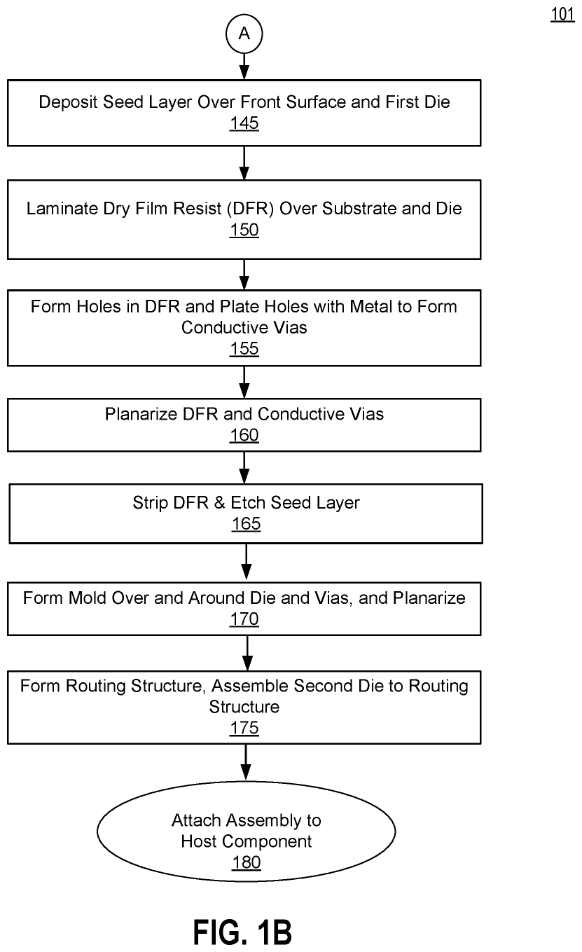

As illustrated in FIGS. 1A and 1B, a variety of fabrication methods may be practiced to form an IC device package assembly having one or more of the features described herein. FIGS. 1A and 1B illustrate a flow diagram of methods for forming an IC device package comprising a substrate core and a die within the substrate core, in accordance with some embodiments. In embodiments, the die has a z-height, i.e., a distance in the z-direction, that is less than a z-height of the substrate core. The z-height of the substrate core is greater than the z-height of the die by a height difference. The die includes conductive contacts at a first side and may include a DTC. Conductive vias extend through a dielectric material from the conductive contacts on the die to the first surface of the substrate core. The conductive vias may extend a distance that is at least eighty percent of the height difference. A substrate may include an electrical routing structure is built up over at least one side of the substrate core. One or more integrated circuit (IC) die may be attached to the substrate and coupled with the die within the substrate core. The substrate core may include one or more voltage regulation (VR) circuitry components. The VR circuitry may be for providing power to the one or more die coupled to the substrate.

Methods 101 begin at input block 110 where a workpiece is received. The workpiece may be prepared upstream of methods 101 and may be in a large panel format, a wafer format, or the like. The workpiece may have been previously formed into any shape suitable for a packaging workpiece, such as rectangular in plan view, i.e., in the x-y plane. The workpiece comprises a substrate. The substrate comprises a substrate core and one layer or multiple layers on the substrate core. In embodiments, the substrate core may have a metal layer on a first surface, the second surface, or on both the first and second surfaces, e.g., the workpiece may be a copper clad laminate material.

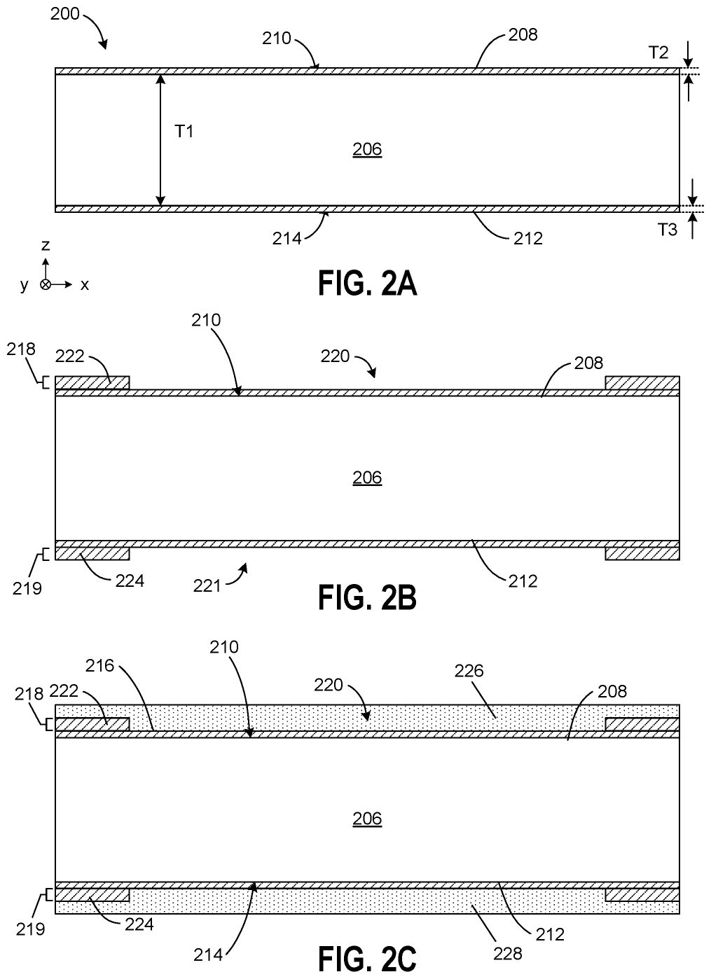

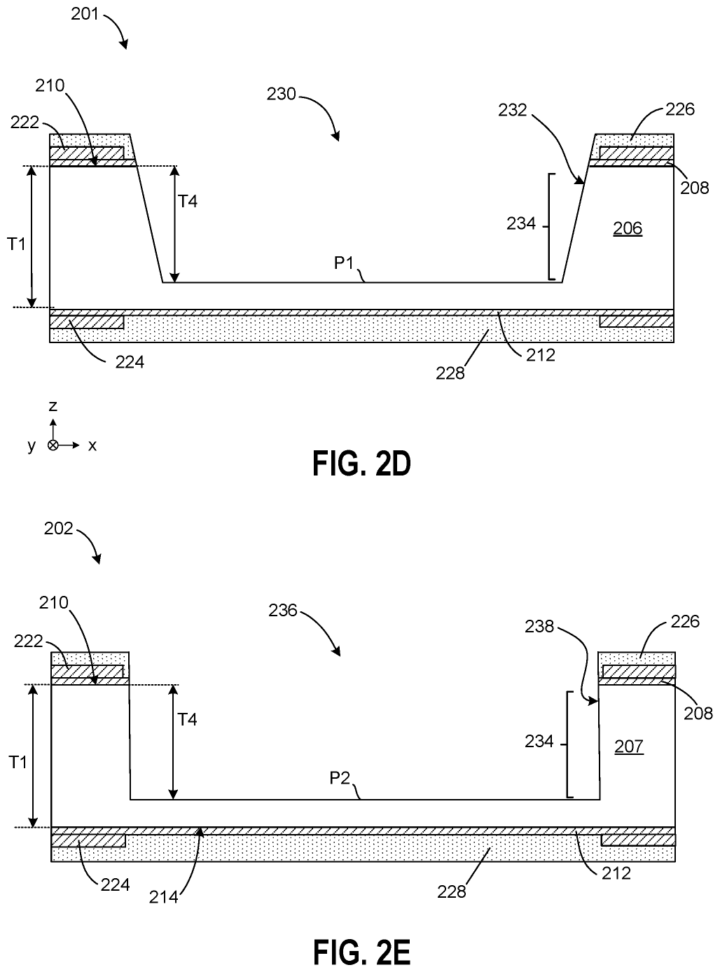

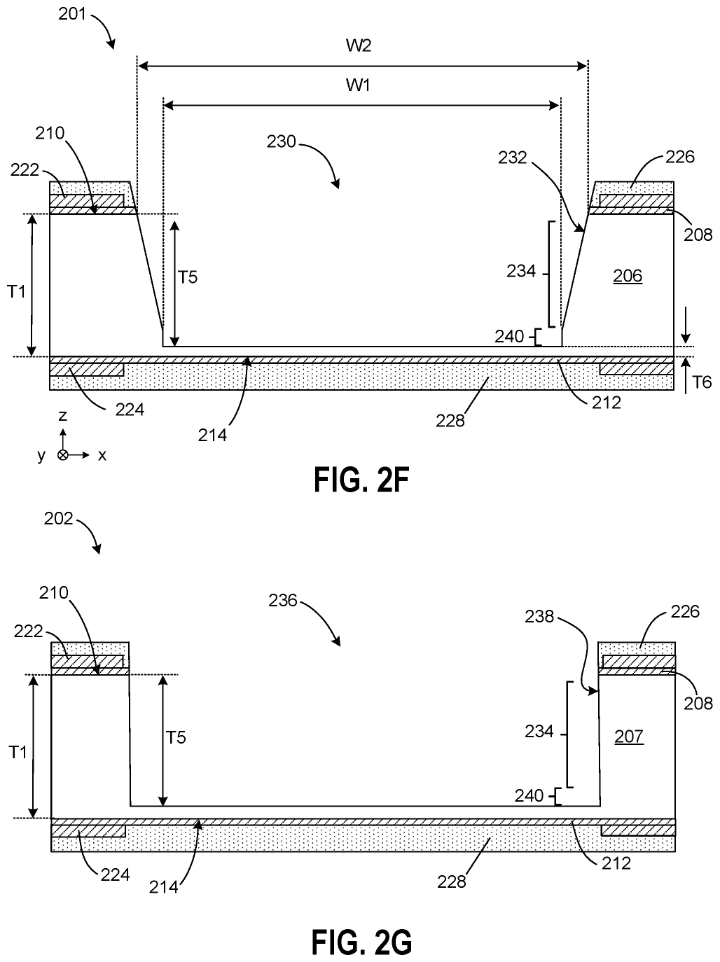

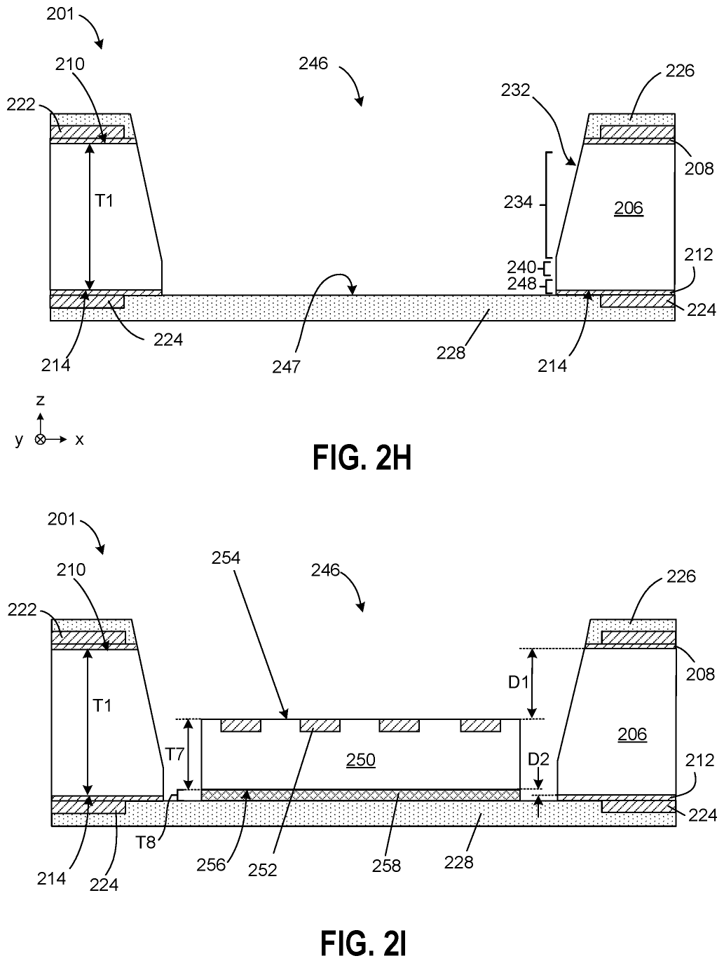

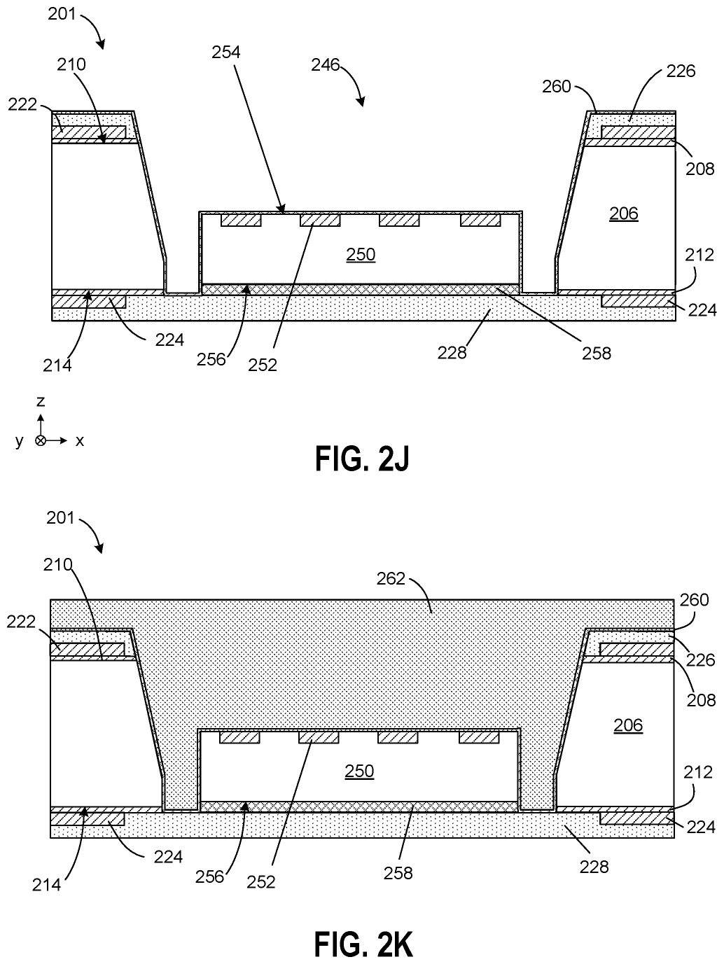

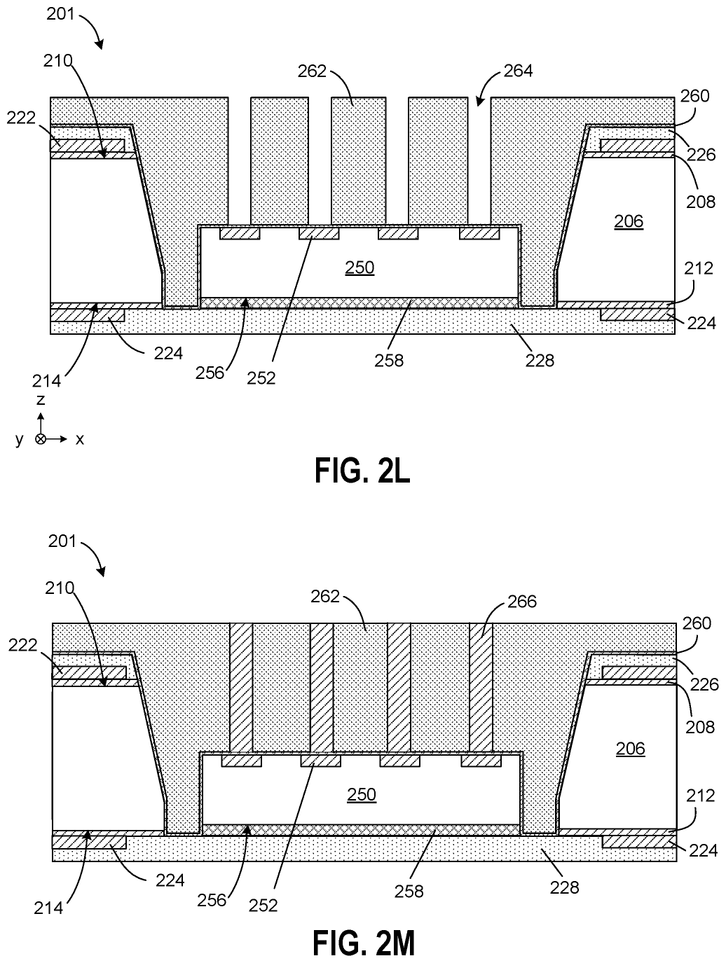

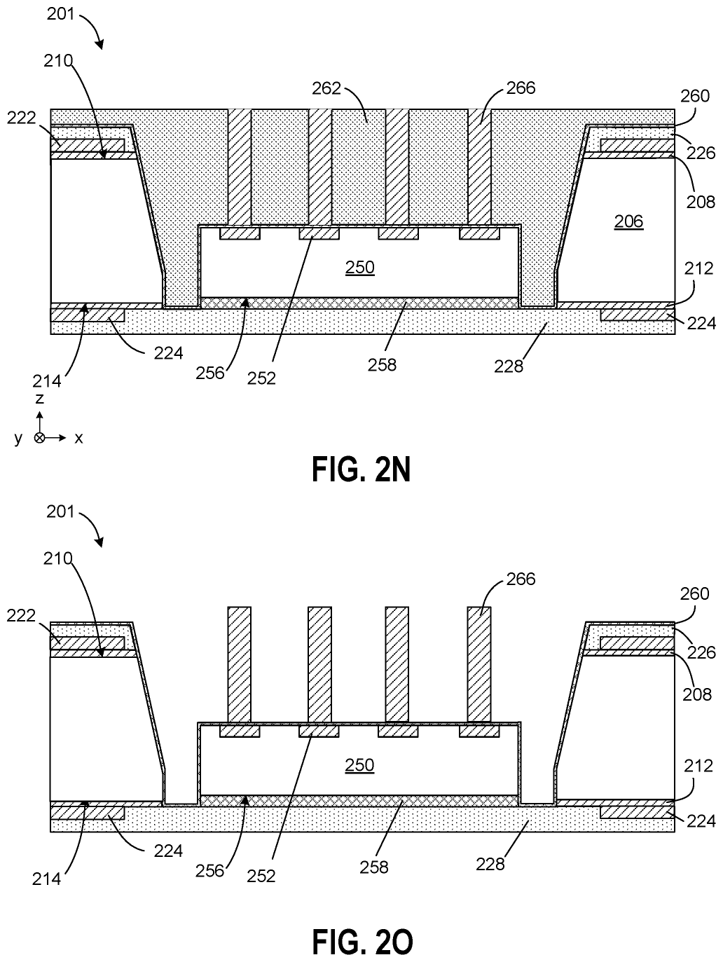

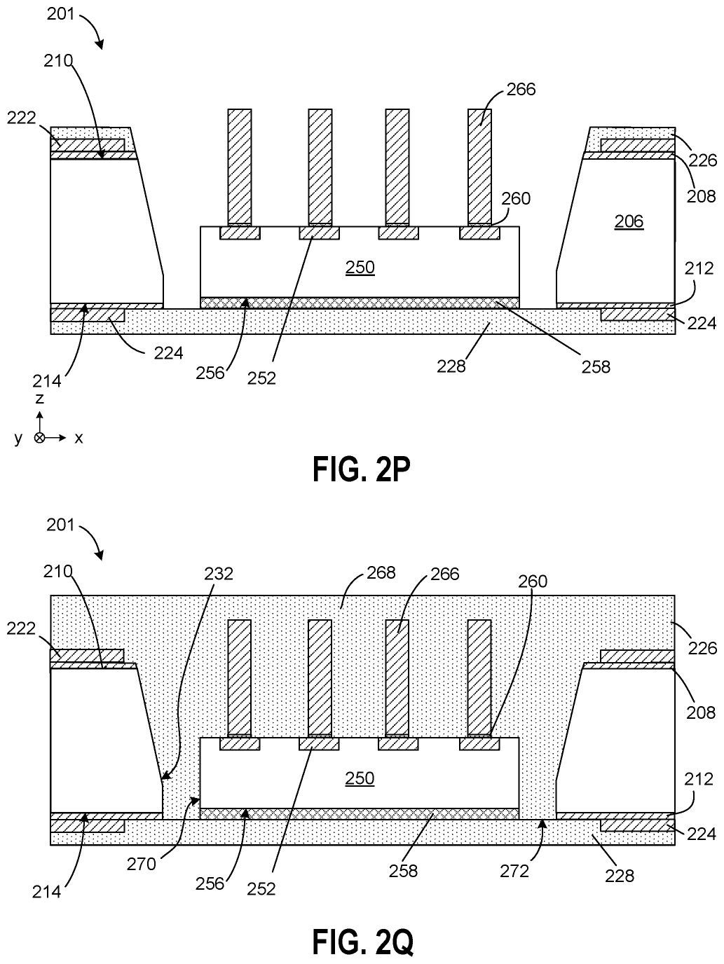

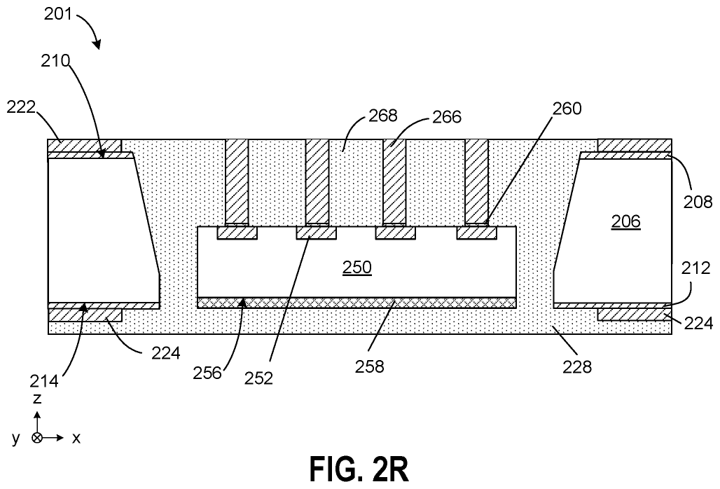

FIG. 2A is a cross-sectional view of an exemplary workpiece 200 comprising a substrate core 206. The substrate core 206 includes a first surface 210 and a second surface 214 opposite the first surface. First surface 210 may be referred to as a “front” surface or a “front side” surface, and second surface 214 may be referred to as a “back” surface or a “back side” surface. The substrate comprises a “front side” metal layer 208 over the front surface 210, and a “back side” metal layer 212 over back surface 214. Substrate core 206 may include one or more material layers. In embodiments, the front side metal layer 216 and back side metal layer 212 are copper or compositions that comprise copper. The compositions of front side metal layer 216 and back side metal layer 212 may be the same or different.

In some embodiments, the substrate core 206 comprises one or more an organic material or materials, e.g., epoxy. In embodiments in which the substrate core comprises organic material(s), the materials may include fillers, e.g., glass cloth or fibers. In some embodiments, the substrate core 206 comprises silicon. In some embodiments, the substrate core 206 comprises glass. In some embodiments, the substrate core may include both organic materials and glass.

In embodiments in which the substrate core comprises glass, the glass may comprise a glass that is predominantly silicon and oxygen. In some embodiments, the glass comprises at least 23 percent silicon and at least 26 percent oxygen, by weight (i.e., wt. %). A substrate core comprising glass may further include one or more additives, such as, aluminum, boron, magnesium, calcium, barium, tin, sodium, potassium, strontium, phosphorus, zirconium, lithium, titanium, or zinc. In some embodiments in which the substrate core comprises glass, the glass comprises at least 23 wt. % Si and at least 26 wt. % O, the glass further comprises at least 5 wt. % Al. Additives within the glass may form suboxides (A₂O) monoxides (AO), binary oxides (AO₂), ternary oxides (ABO₃), and mixtures thereof. For example, the glass may comprise AlOₓ (e.g., Al₂O₃), BOₓ (e.g., B₂O₃), MgOₓ (e.g., MgO), CaOₓ (e.g., CaO), STOₓ (e.g., SrO), BaOₓ (e.g., BaO), SnOₓ (e.g., SnO₂), NaOₓ (e.g., Na₂O), KOₓ (e.g., K₂O), POₓ (e.g., P₂O₃), ZrOₓ (e.g., ZrO₂), LiOₓ (e.g., Li₂O), TiOₓ (e.g., TiO₂), or ZnOₓ (e.g., ZnO₂). Depending on chemical composition, the glass may therefore be referred to as silica, fused silica, aluminosilicate, borosilicate, or alumino-borosilicate, for example.

In embodiments in which substrate core 206 comprises a glass, it is advantageously a bulk material of substantially homogeneous composition in contrast to a composite material that may merely comprise glass fillers and/or fibers. Although the substrate core 206 comprising glass is substantially amorphous in some embodiments, the glass may also have other morphology or microstructure, such as polycrystalline (e.g., nanocrystalline).

In embodiments in which substrate core 206 comprises a glass, one or more material layers may clad either or both of the front surface 210 or back surface 214 of the substrate core so that it is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of a substrate core comprising a glass. Organic material layers, such as polymer dielectric materials, may also clad one or more sides of a substrate core comprising glass. Hence, while an embodiment in which substrate core 206 comprises a glass is advantageously substantially free of organic materials (e.g., no adhesives, etc.), a workpiece may include organic material within a substrate stack that includes glass.

In embodiments, one or more voltage regulation (VR) circuitry components may be disposed within the substrate core 206. The VR circuitry may be for providing power to one or more die coupled with an IC device package assembly. The components may include any suitable circuit component, such as resistors, inductors, capacitors, or transistors. With respect to a capacitor, it may be a DTC deep-trench capacitor (DTC) pre-formed in a separate process from the process for fabricating the IC device package. Preforming a capacitor is advantageous because forming a capacitor, such as a DTC requires a process with a relatively large number of stages. In addition, the capacitor itself, when included within a substrate core, only consumes a relatively small portion of the plan view area of the core. For these reasons, it can be more efficient to preform numerous capacitors in a separate process rather than form one or a few capacitors within a substrate core during an IC device package assembly process. After the capacitors are formed, a wafer containing multiple capacitors can be cut into multiple die, each die comprising a capacitor, and a die can be placed within an opening in the core 206 during one stage of forming the IC device package assembly. However, the z-height of the die containing a capacitor may be limited by the capacitor forming process. When a capacitor is formed this way—in a process different from the process used to form the IC device package assembly—the maximum z-height of the die containing a capacitor (or other discrete component) may be less than a thickness T1 of substrate core 206.

The thickness T1 of substrate core 206 may be greater than the z-height of a die comprising a capacitor for a variety of reasons. One reason is that the substrate core 206 may include one or more inductors. The z-thickness the substrate core 206 may need to be sufficient to accommodate any inductors within the substrate core. Substrate core 206 has a thickness T1 that may vary with implementation. Thickness T1 is typically in a range from 700 μm to 3000 μm, however, in some embodiments, thickness T1 may be as low as 100 μm or greater than 3000 μm. Front side metal layer 216 and back side metal layer 212 have respective thicknesses T2 and T3 that may vary with implementation. The thicknesses T2 and T3 may be the same or different. Thicknesses T2 and T3 may be in the range of 15 μm to 70 μm however, in some embodiments, thicknesses T2 and T3 may be as low as 10 μm or up to 150 μm.

Referring to FIG. 1A, methods 101 continue at block 115 where metal layers are formed over first surface 210, second surface 214, or over both surfaces. After formations of metal layers, holes are created in the layer to define metal features. The metal layer formed over the first surface may be referred to as a “first” metal layer. The metal layer formed over the second surface may be referred to as a “second” metal layer. The metal layers and metal features may be formed in various ways. For example, first metal layer may be formed by a subtractive process in which a metal is deposited on a surface a mask is placed over the metal layer, and locations not blocked by the mask are etched. In another example, first metal layer may be formed by an additive process in which a metal is added to specific areas using selective masking or printing. In some examples, the first metal layer may be formed in a semi-additive process.

FIG. 2B is a cross-sectional view of the workpiece 200 after exemplary first metal layer 218 and second metal layer 219 have been formed. First and second metal layers 218, 219 include holes 220, 221 at locations where metal is absent from the layer. The holes 220, 221 may define a plurality of first metal features 222 in first metal layer 218, and a plurality of second metal features 224 in metal layer 219. First and second metal layers 218, 219 may comprise any suitable electrically conductive metal, e.g., copper, aluminum, silver, etc. First and second metal layers 218, 219 have thicknesses that may vary with implementation. In embodiments, the thicknesses of the first and second metal layers 218, 219 may be 15 μm to 70 μm. While workpiece 200 illustrates a single hole on each side, and two metal features on each side, it should be appreciated that workpiece 200 may extend laterally (in the x-dimension) and include as many holes and metal features as desired on either side.

Referring to FIG. 1A, methods 101 continue at block 120 where a dielectric layer is formed over first metal layer 218 and front surface 210. In addition, block 120 may include forming a dielectric layer over second metal layer 219 and back surface 214. FIG. 2C illustrates a cross-sectional view of the workpiece 200 after a first dielectric layer 226 has been formed over first metal layer 218 at first surface 210, and a second dielectric layer 228 has been formed over back surface 214. First and second dielectric layers 226 and 228 may have the same composition, or may have different compositions. First and second dielectric layers 226 and 228 may comprise any suitable dielectric material (e.g., polymer materials, silicon dioxide (SiO₂), silicon nitride (Si₃N₄), etc.) and may be formed by any suitable technique, e.g., by deposition, lamination, plasma-enhanced chemical vapor deposition (PECVD), etc. In some embodiments, a dielectric material may be dielectric/organic materials, resins, epoxies, polymer adhesives, silicones, acrylics, polyimides, cyanate esters, thermoplastics, and/or thermosets. In embodiments, the dielectric layers 226 and 228 may be ABF. In embodiments, the dielectric layers 226 and 228 may be any suitable thicknesses. First and second dielectric layers may have the same thickness, or may have different thicknesses.

Referring to FIG. 1A, methods 101 continue at block 125 where a cavity is formed in the substrate core 206 to a first depth at the front surface 210. The cavity may be within hole 220 and between first metal features 222. The cavity may be formed in various ways, e.g., a mechanical cutting tool, such as a drill bit, router, or fly cut tool. The cavity extends through dielectric layer 226, front side metal layer 208, and into substrate core 206 to a first depth T4. The first depth T4 may be about 70 to 95 percent of the thickness T1 substrate core 206. The cavity 230 may include a sidewall that may be perpendicular to the front or back surfaces, or outward sloping, depending on the type of cutting tool used.

FIG. 2D illustrates a cross-sectional view of a substrate core 206 after formation of a cavity 230 in a first example. In the example, cavity 230 includes a sidewall 232 in a first sidewall region 234 proximate front side metal layer 208 and front surface 210. In the example of FIG. 2D, sidewall 232 slopes outward, i.e., away from the center of the cavity 230. As illustrated in FIG. 2D, an opening of cavity 230 at the front surface 210 is larger than an opening at a deepest point “P1” of the cavity 230.

FIG. 2E is a cross-sectional view of a substrate core 207 after formation of a cavity 230 according to another example. In the example of FIG. 2E, a sidewall 238 is approximately perpendicular to first surface 210 and/or back surface 214. In the example, an opening of cavity 236 at front surface 210 may be approximately the same as the x-width of the cavity 236 at the deepest point “P2.”

In embodiments, sidewalls 232 and 238, within first sidewall region 234, may have a first average surface roughness of between about 200 nm and about 15 μm, depending on the type of cutting tool used and the material composition. For example, an organic material, which may include glass cloth (protruding fibers), will have a greater roughness than a glass material.

Referring to FIG. 1A, methods 101 continue at block 130 where additional material is removed to increase the depth of cavity to a second depth. The depth of the cavity may be increased in various ways, e.g., laser drilling. FIG. 2G and FIG. 2H illustrate cross-sectional views of substrates 206 and 207, respectively, after additional material has been removed to increase the depth of cavity 230 and cavity 236. The depth of cavity 230 and cavity 236 are each increased to a second depth T5. The second depth T5 may be about 95 to 99 percent of substrate core 206 thickness T1. After increasing the depth of the cavity at block 135, a thickness or depth T6 of the remaining substrate core material may be about 500 nm to 5 μm. After increasing cavity depth at block 135, sidewalls of the cavity include a second sidewall region 240 in addition to first sidewall region 234. The second sidewall region 240 is proximate to backside metal layer 212 and back surface 214. As illustrated in FIG. 2F and FIG. 2G, respectively, the portions of sidewalls 232 and 238 within second sidewall region 240 may be approximately perpendicular to first surface 210 and/or back surface 214. In addition, the portions of sidewalls 232 and 238 within second sidewall region 240 may be approximately perpendicular to first metal layer 218. In embodiments, sidewalls 232 and 238 within second sidewall region 240 may have a second average surface roughness of about 200 nm to 15 μm, depending on the material composition.

In embodiments, the second average surface roughness of sidewalls 232, 238 within second sidewall region 240 is less than the first average surface roughness of the sidewalls in first sidewall region 234. The difference in surface roughness in the sidewall regions may be due to the use of the different material removal tools, e.g., cutting with a mechanical tool versus laser tool.

In examples in which sidewall 232 slopes outward (e.g., substrate core 206), a surface of cavity 230 proximate front surface 210 (which will be referred to as an “opening”) comprises a first size. The opening of cavity 230 proximate front surface 210 comprises a second size. The first and second sizes may be two-dimensional areas in the x-y plane, or one-dimensional cross-sectional dimensions, e.g., a width in the x- or y-dimension. In one example, the opening of cavity 230 proximate the back surface 214 has a width in the x-dimension of W1. In addition, the opening of cavity 230 proximate the front surface 210 has a width in the x-dimension of W2. As may be seen in FIG. 2G, W2 is greater than W1. In embodiments, the depth of a cavity in substrate core may be increased (in a subsequent stage) to form a through hole through the core. The opening of the through hole that is proximate to the front surface 210 may be a first opening, and an opening of the through hole proximate to the back surface 214 may be a second opening. The first opening may be of a first size, e.g., W2, the second opening may be of a second size, e.g., W1, where the first size is greater than the second size.

Referring again to FIG. 1A, methods 101 continue at block 135 where a portion of the front side metal layer at the front surface of the substrate core is removed. Operations at block 140 remove the thin layer of core material remaining in cavity 230. In addition, operations at block 140 removes the portion of the backside metal layer 212 at the bottom of the cavity. As a result, cavity 230 extends through substrate core 206 and backside metal layer 212, thereby becoming a hole through the substrate core. The thin layer of core material remaining in cavity 230 and the backside metal layer 212 may be removed in any suitable way known in the art. In some embodiments, materials are removed using a copper etch process.

FIG. 2H illustrates a cross-sectional view of the substrate core 206 after core material in cavity 246 and backside metal layer 212 at the bottom of the cavity have been removed, exposing surface 247 of dielectric material layer 228. As illustrated in the example of FIG. 2H, substrate core 206 comprises a hole 246 extending from front surface 210 to surface 247 of the dielectric material layer 228, which is near back surface 214 and in a plane that is parallel to the plane of back surface 214. The depth of the hole 246 may be the thickness of the substrate core T1, i.e., the distance between front surface 210 and back surface 214. The hole 246 includes sidewall 232, which comprises first sidewall region 234, second sidewall region 240, and a third sidewall region 248. The third sidewall region 248 includes a portion of backside metal layer 212. In embodiments, the portion of sidewall 232 within third sidewall region 248 has a third average surface roughness of about 50 nm to 500 nm, depending on the material composition. In embodiments, the third average surface roughness of sidewall 232 within third sidewall region 248 is less than the first average surface roughness of the sidewall 232 in first sidewall region 234.

The operations of methods 101 at block 135 (and thereafter) may be substantially the same whether performed with respect to the example of substrate core 206 shown in FIG. 2F or the example substrate 207 shown in FIG. 2G. A primary difference between these examples is the slope of the sidewall. While FIG. 2H is presented as a representation of processing performed on substrate core 206 shown in FIG. 2F, figures showing subsequent processing stages of the example substrate 207 depicted in FIG. 2G are omitted so as to not obscure principals and features of the disclosed embodiments.

Referring to FIG. 1B, methods 101 continue at block 140 where a first die is placed in the hole 246 and attached to surface 247 of dielectric material layer 228. The first die may be placed in any suitable way known in the art, such as with a pick and place tool. The first die may be attached to surface 247 with a thermal bonding film (TBF), which may be referred to herein as a “bond film” or an adhesive organic film. The first die may include conductive contacts at one or both sides of the die. In some embodiments, the first die may comprise one or more discrete circuit elements, such as capacitor, inductors, resistors, or transistors. FIG. 2I illustrates a cross-sectional view of the substrate core 206 after a first die 250 has been placed within hole 246 and attached to surface 247 of dielectric material layer 228. The first die 250 may have a z-height or thickness T7 that is less than the z-height or thickness T1 of substrate core 206. In some embodiments, first die 250 may have a maximum thickness T7 of 650 μm to 700 μm. In embodiments, the first die 250 comprises one or more DTCs. The first die 250 includes conductive contacts 252 at a top side 254. First die 250 includes a bottom side 256 opposite to top side 254. As illustrated, a bond film 258 may be disposed between bottom side 256 and surface 247 of dielectric material layer 228. First die 250 is mechanically coupled to dielectric material layer 228 by the bond film 258. In some embodiments, bond film 258 may be a polymer adhesive comprising any suitable polymer with a good adhesive property after curing. In some embodiments, the thickness T8 of bond film 258 is typically about 5 μm, but may be between about 2 μm and 10 μm.

The first die 250 may be nearer to the back surface 214 than to front surface 210. As shown in FIG. 2I, the substrate core has a first height, e.g., thickness T1, and the first die 250 has a second height, e.g., thickness T7. The first height is greater than the second height by a height difference. The height difference is the sum of D1 and D2. Distance D1 is the distance between the top side 254 of first die 250 and front surface 210 of the substrate core 206. Distance D2 is the distance between bottom side 256 of first die 250 and (the plane of) back surface 214 of substrate core 206. For example, for a first height of 1000 μm, a second height of 650 μm, a distance D1 of 350 μm, and a distance D2 of 50 μm, the height difference is 400 μm. The ratio of D1 to the height difference is 350/400 μm, which is 88% of height difference. In embodiments, distance D1 is equal to at least eighty percent (80%) of the height difference. In embodiments, distance D1 is equal to at least eighty five percent (85%) of the height difference.

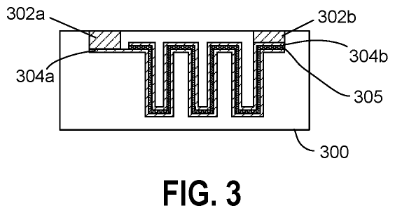

FIG. 3 illustrates a cross-sectional view of a die 300 comprising a capacitor, according to one example. In some embodiments, the first die 250 may be the same as or similar to die 300. In an embodiment, die 300 may comprise a deep trench capacitor (DTC). The example die 300 includes conductive contacts 302a and 302b. Conductive contact 302a is electrically coupled with metal structure 304a. Conductive contact 302b is electrically coupled with metal structure 304b. Metal structures 304a and 304b are separated by a dielectric 305.

Referring again to FIG. 1B, methods 101 continue at block 145 where a seed layer is deposited over front surface and first die. FIG. 2J illustrates a cross-sectional view of the substrate core 206 after a seed layer 260 has been deposited over front surface 210 and first die 250. The seed layer 260 may be deposited by an electroless method, such as PVD, CVD, or ALD. Seed layer 260 may be any suitable conductive material, such as copper, or a mixture of copper and titanium.

Referring again to FIG. 1B, methods 101 continue at block 150 where a dry film resist (DFR) is laminated over the surface of the substrate core. FIG. 2K illustrates a cross-sectional view of the substrate core 206 after a dry film resist 262 has been laminated to seed layer 260, which is over dielectric layer 226 and first die 250 within the hole 246. The dry film resist material 262 may be applied using any suitable method. In one example, the dry film resist material 262 may be placed against substrate core 206 and first die 250, and laminated to the surfaces with heat and/or pressure.

Referring again to FIG. 1B, methods 101 continue at block 155 where holes are formed in the DFR material 262, and the holes are filled with metal to form conductive vias. FIG. 2L illustrates a cross-sectional view of the substrate core 206 after holes 264 have been formed in the DFR material 262. FIG. 2M illustrates a cross-sectional view of the substrate core 206 after the holes are filled with metal, e.g., electroplated with copper, to form conductive vias 266. As shown in FIG. 2M, each conductive via 266 is electrically coupled with a conductive contact 252 of first die 250. Seed layer 260, which may comprise Cu, Ti, or other conductive material, is between each conductive via 266 and a conductive contact 252. While not shown in the figure, conductive contacts or pads may be formed on conductive vias 266 at the surface of the DFR material 262 above first surface 210.

Referring again to FIG. 1B, methods 101 continue at block 160 where DFR material 262 and conductive vias 266 are planarized. FIG. 2N illustrates a cross-sectional view of the substrate core 206 after DFR material 262 and conductive vias 266 have been planarized.

Referring again to FIG. 1B, methods 101 continue at block 165 where DFR material 262 and seed layer 260 are removed. FIG. 2O illustrates a cross-sectional view of the substrate core 206 after the DFR material 262 has been stripped, leaving conductive vias 266 exposed. The DFR material 262 may be stripped using any suitable chemical etch. FIG. 2P illustrates a cross-sectional view of the substrate core 206 after the seed layer 260 has been removed. Seed layer 260 may be removed using any suitable chemical etch, e.g., a Ti/Cu chemical etch. As shown in FIG. 2P, portions of seed layer 260 between each conductive vias 266 and conductive contacts 252 may remain after operations at block 165.

Referring again to FIG. 1B, methods 101 continue at block 170 where a dielectric material, such as mold, may be formed over and around first die 250 and conductive vias 266. In addition, after the dielectric material has been formed, the conductive vias and dielectric material may be planarized. FIG. 2Q illustrates a cross-sectional view of the substrate core 206 after dielectric material 268 has been formed over and around first die 250 and conductive vias 266. In some embodiments, the dielectric material 268 may be between sidewall 232 of the substrate core and a sidewall 270 of the first die 250. In some embodiments, the dielectric material 268 may include a side or surface 272 that contacts second dielectric layer 228. Side 272 of dielectric material 268 may be substantially coplanar with back surface 214 of substrate core 206. In some embodiments, bottom side 256 of first die 250 may lie in a plane that is parallel with the plane of back surface 214, wherein the first and second planes are close to each other or spaced apart by a small distance, e.g., a distance less than or equal to the thickness of bond film 258, as illustrated in FIG. 2Q.

Dielectric material 268 may be any suitable an organic, such as an epoxy or Ajinomoto Build-up Film (ABF). Dielectric material 268 may be any alternative material known to be suitable for IC chip packaging applications. The processing and techniques for encasing integrated circuit device in a mold material layer are well known in the art and for purposes of clarity and conciseness are not discussed herein. Any suitable methods known in the art may be employed.

FIG. 2R illustrates a cross-sectional view of the substrate core 206 after the conductive vias and dielectric material have been planarized. Planarization may expose first metal features 222. For example, a grind and/or polish process may partially remove and/or planarize the dielectric material 268 to reveal the conductive vias 266 and first metal features 222.

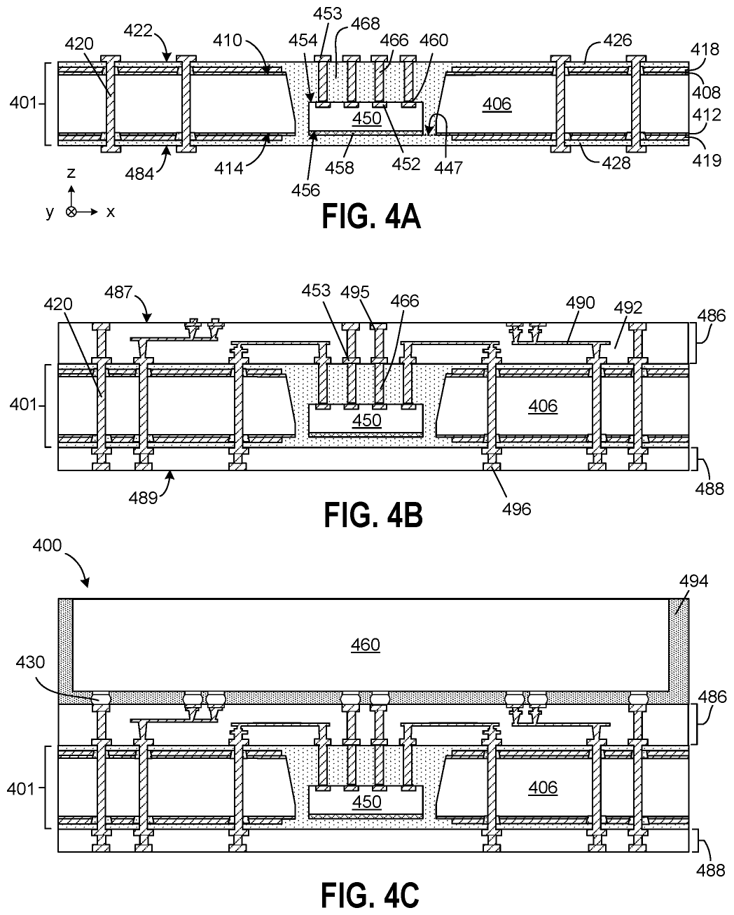

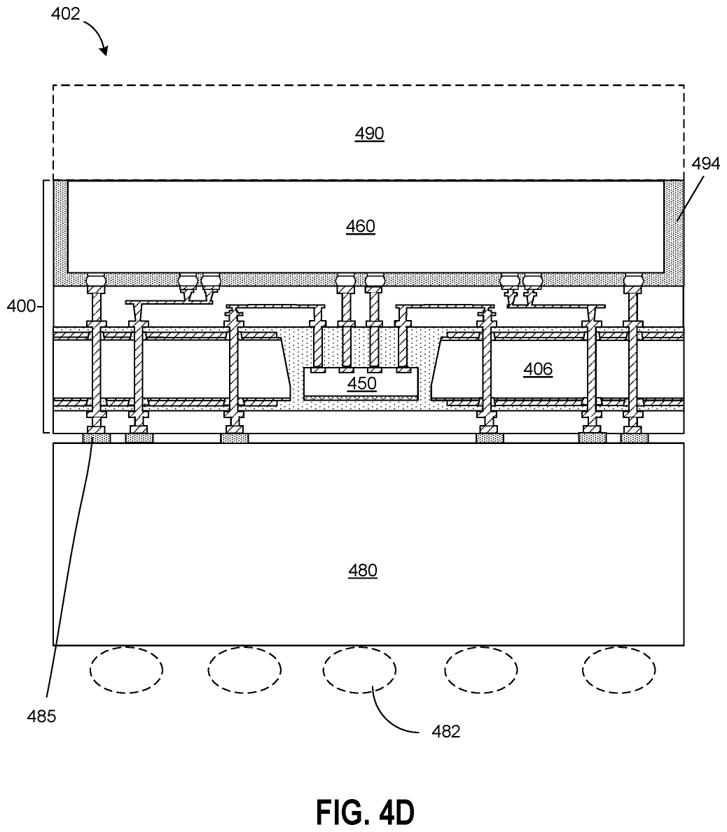

Referring again to FIG. 1B, methods 101 continue at block 175 where an electrical routing structure is built up over at least one side of a substrate core prior to assembly with IC die. In addition, one or more integrated circuit (IC) die are assembled to the routing structure at block 175. FIG. 4A illustrates a cross-sectional view of a substrate core 406 that may be the same as or similar to substrate core 206. Substrate core 406 is used to illustrate embodiments that may not be readily seen in illustrations of substrate core 206. FIG. 4B illustrates a cross-sectional view of a substrate 401, which includes the substrate core 406, after an electrical routing structure has been built up over at least one side of the substrate. FIG. 4C illustrates a cross-sectional view of substrate 401 after an IC die is assembled to a routing structure.

Referring to FIG. 4A, in various embodiments, a substrate 401 includes substrate core 406 with a front side metal layer 408 on a first surface 410 and a backside metal layer 412 on a back surface 414. Front side metal layer 408 and backside metal layer 412 may be the same as or similar to front side metal layer 208 and backside metal layer 212, respectively. The substrate core 406 includes a first metal layer 418 and a second metal layer 419, which may be the same as or similar to first metal layer 218 and second metal layer 219, respectively. The first and second metal layers 418, 419 may include metal features (not shown), which may be the same as or similar to first metal features 222 and second metal features 224. Dielectric layers 426 and 428, which may be the same as or similar to dielectric layers 226 and 228, are over substrate core 406. A first die 450 is within substrate core 406. First die 450 may be the same as or similar to first die 250. The first die 450 includes conductive contacts 452 at a top side 454, which are coupled with conductive vias 466. A seed layer 460 may be between the conductive contacts 452 and conductive vias 466. A dielectric material 468 may be over and around first die 450 and conductive vias 466. Dielectric material 468 may have dimensions, spatial relationships with other features of the substrate core 406, and a composition that is the same as or similar to the dielectric material 268. Conductive vias 466 extend through dielectric material 268 between conductive contacts 452 of the first die 250 and conductive contacts 453 at a top surface of the dielectric material 268. First die 450 includes a bottom side 456 opposite to top side 454. As illustrated, a bond film 458 may be disposed between bottom side 456 and a surface 447 of dielectric material layer 428. Bond film 458 may have a composition that is the same or similar to the composition of bond film 258. The substrate 401 includes through-substrate vias (TSV) 420 that extend through substrate core 406 between a front surface 422 and a back surface 484.

FIG. 4B is a cross-sectional view of substrate 401 after an electrical routing structure 486 has been built up over front surface 422 of the substrate. In addition, the figure shows an electrical routing structure 488 that has been built up over back surface 484. Electrical routing structure 486 includes a front surface 487 opposite a surface facing substrate 401. Electrical routing structure 488 includes a back surface 489 opposite a surface facing substrate 401. The electrical routing structures may be electrically coupled to the conductive vias 466, TSVs 420, and conductive contacts 453. The electrical routing structures may, for example, comprise one or more levels of metallization features embedded within any suitable dielectric material. The electrical routing structures may interconnect one or more IC die (including die 450 and IC die attached to the routing structure) to each other and/or couple the one or more of IC die to the conductive vias 466, TSVs 420, and conductive contacts 453.

In the example illustrated in FIG. 4B, a routing structure 486 has been built-up over front surface 422. Routing structures 486, 488 comprises one or more levels of RDL metallization features 490 embedded within one or more layers of dielectric material 492. RDL metallization features 490 may comprise one or more metals, with one example being predominantly copper. At least some of RDL metallization features 490 are to electrically coupe first die 450 with conductive contacts 495 at front surface 487 of routing structure 486. Furthermore, at least some of RDL metallization features 490 are to electrically coupe first die 450 with conductive contacts 496 at back surface 489 of routing structure 488. Routing structures 486, 488 further comprise metallization features 490 that are to interconnect multiple IC dies to conductive TSVs 420.

Depending on the embodiment, dielectric material 492 may be any of a molding compound, a spin-on material, or dry film laminate material, for example. Dielectric material 492 may be introduced wet/uncured into a cast and then dried/cured. Alternatively, dielectric material 492 may be introduced as a semi-cured dry film that is fully cured following its application to substrate 401.

The composition of dielectric material 492 may vary with implementation. In some advantageous embodiments, dielectric material 492 is an organic dielectric, such as, an epoxy resin, phenolic-glass, or a resinous film such as the GX-series films commercially available from Ajinomoto Fine-Techno Co., Inc. (ABF). Dielectric material 492 may comprise epoxy resins (e.g., an acrylate of novolac such as epoxy phenol novolacs (EPN) or epoxy cresol novolacs (ECN)). In some specific examples, dielectric material 492 is a bisphenol-A epoxy resin, for example including epichlorohydrin. In other examples, dielectric material 492 includes aliphatic epoxy resin.

FIG. 4C illustrates a cross-sectional view of substrate 401 after an IC die is assembled to a routing structure 486. A package dielectric 494, such as a mold material, may surround sidewalls of IC die 460. The IC die may comprise any electrical circuitry, with one example being logic circuitry comprising logic gates. The IC die assembled may also comprise any photonic circuitry suitable for the detection, emission or processing (e.g., filtering, multiplexing and demultiplexing) of optical signals. While only one IC die is illustrated in the figure, two or more IC die may be assembled to a routing structure in other embodiments.

In the example illustrated in FIG. 4C, IC die 460 is assembled to interconnect interfaces within a top metallization level of routing structure 486 of an IC device package structure 400. IC die 460 may be directly bonded to routing structure 486, or, electrically coupled through intervening electrical interconnects 430, which may comprise solder of any suitable composition. In the example illustrated, IC die 460 is flip-chip attached with integrated circuitry within the die being proximal to front surface 487.

IC die 460 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, IC die 460 includes one or more banks of active repeater circuitry to improve multi-die interconnects (e.g., network-on-chip architectures). In other examples, IC die 460 includes clock generator circuitry or temperature sensing circuitry. In other examples, IC die 460 include logic circuitry that, along with other IC die implement multi-chiplet aggregated logic circuitry (e.g., mesh network-on-chip architectures). In some specific examples, IC die 460 includes microprocessor core circuitry, for example comprising one or more shift registers.

IC die 460 advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 460 may include active devices other than FETs. For example, IC die 460 may include electronic memory structures, such as magnetic tunnel junctions (MTJs), capacitors, or the like.

IC die 460 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 460 may have a feature pitch ranging from 100 nm to several microns, for example.

Referring again to FIG. 1B, where methods 101 complete at output 180 where the assembled device package structure is attached to any suitable host component. FIG. 4D illustrates an exemplary system 402 including one device package structure 400 attached to a host component 480 with interconnects 485, in accordance with some embodiments. In exemplary embodiments, interconnects 485 are solder (e.g., SAC) microbumps although other interconnect features are also possible. In some embodiments, host component 480 is predominantly silicon. Host component 480 may also comprise one or more alternative materials known to be suitable as interposers or package substrates (e.g., an epoxy preform, cored or coreless laminate board, etc.). Host component 480 may also include a printed circuit board (PCB). Host component 480 may include one or more metallized redistribution levels (not depicted) embedded within a dielectric material. Host component 480 may also include one or more IC die embedded therein.

Host component 480 may include interconnects 482 illustrated in dashed line. Interconnect 482 may comprise any solder (ball, bump, etc.) suitable for a given host board architecture (e.g., surface mount FR4, etc.). Also illustrated in dashed line, one or more heat spreaders and/or heat sinks 498 may be further coupled to device package structure 400, which may be advantageous, for example, where IC die 460 comprises one or more CPU cores or other circuitry of similar power density. Although not illustrated, package dielectric 494 may be background so that heat spreader/sink 498 may be in closer contact with IC die 460.

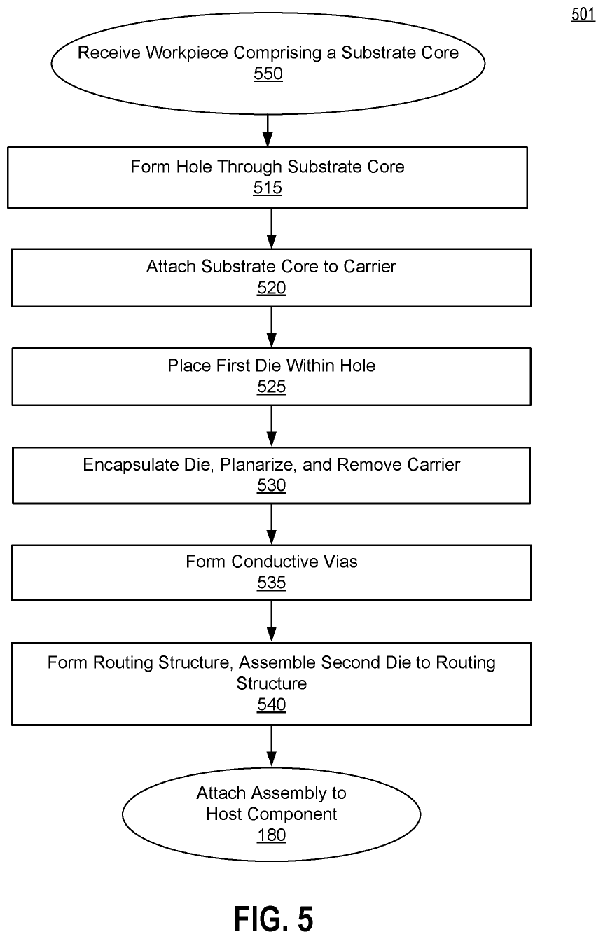

FIG. 5 illustrates a flow diagram of methods for forming an IC device package comprising a substrate core and a die within the substrate core, in accordance with some embodiments. FIG. 5 illustrates a variety of fabrication methods for forming an IC device package assembly that employ a releasable bond film between the bottom side of the first die and a sacrificial panel.

In embodiments, the methods described with respect to FIG. 5 are directed to a die that has a z-height that is less than a z-height of the substrate core. The z-height of the substrate core is greater than the z-height of the die by a height difference. The die includes conductive contacts at a first side and may include a DTC. Conductive vias extend through a dielectric material from the conductive contacts on the die to a first surface of the substrate core. The conductive vias may extend a distance is at least ninety-five percent of the height difference. A substrate may include an electrical routing structure is built up over at least one side of the substrate core. One or more integrated circuit (IC) die may be attached to the substrate and coupled with the die within the substrate core. The substrate core may include one or more voltage regulation (VR) circuitry components. The VR circuitry may be for providing power to the one or more die coupled to the substrate.

Methods 501 begin at input block 510 where a workpiece is received. The workpiece may be prepared upstream of methods 501 and may be in a large panel format, a wafer format, or the like. The workpiece may have been previously formed into any shape suitable for a packaging workpiece, such as rectangular in plan view, i.e., in the x-y plane. The workpiece comprises a substrate core and may include one layer or multiple layers on the substrate core. In embodiments, the substrate core may have a metal layer on a first surface, the second surface, or on both the first and second surfaces, similar to substrate core 206 described herein, however, this is not required. In various embodiments, metal layers on surfaces of the substrate core may be absent.

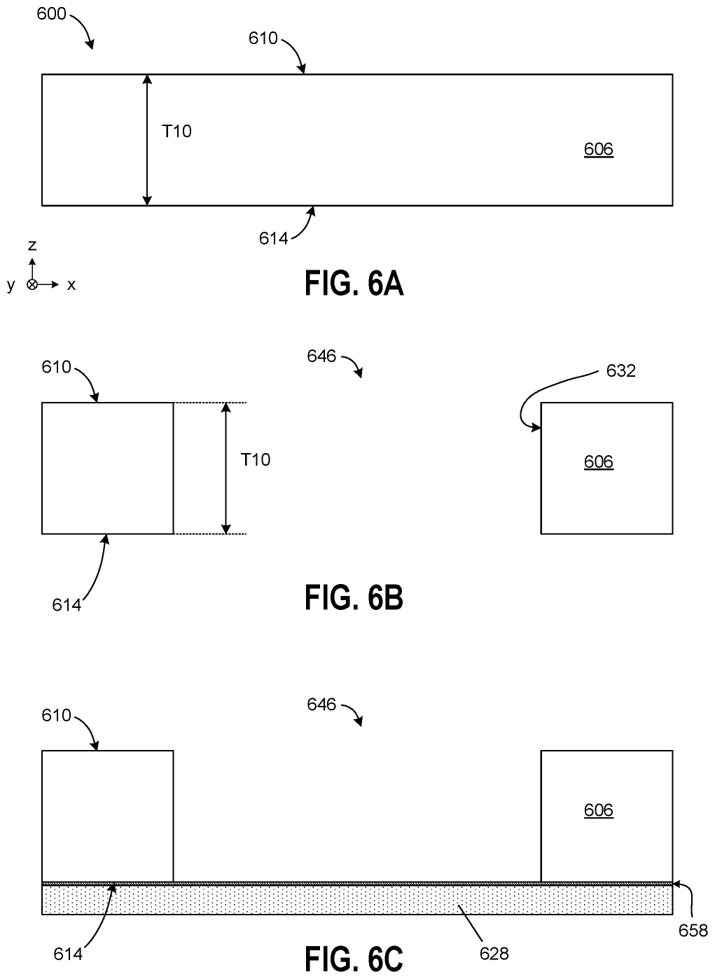

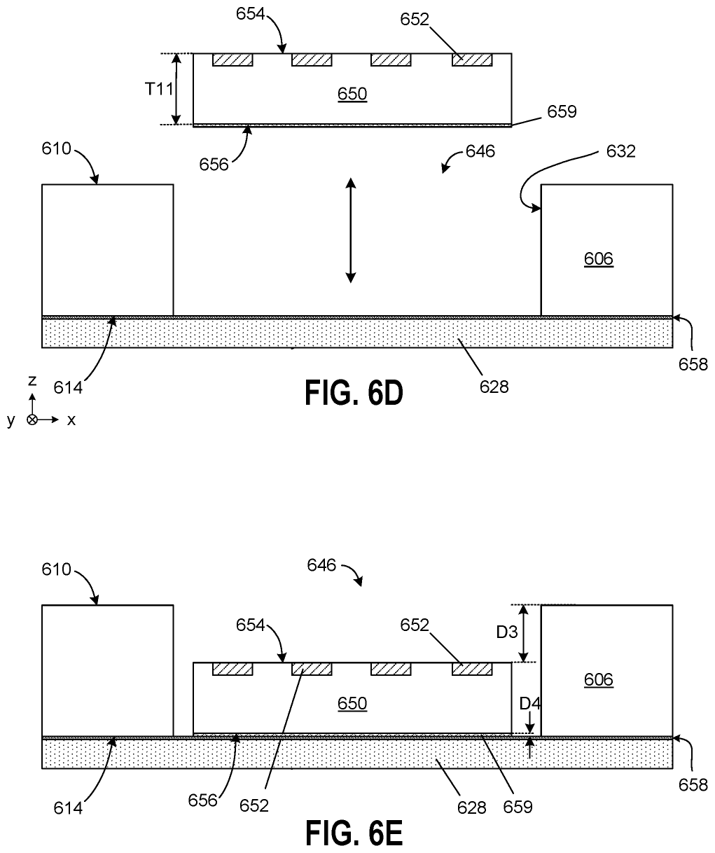

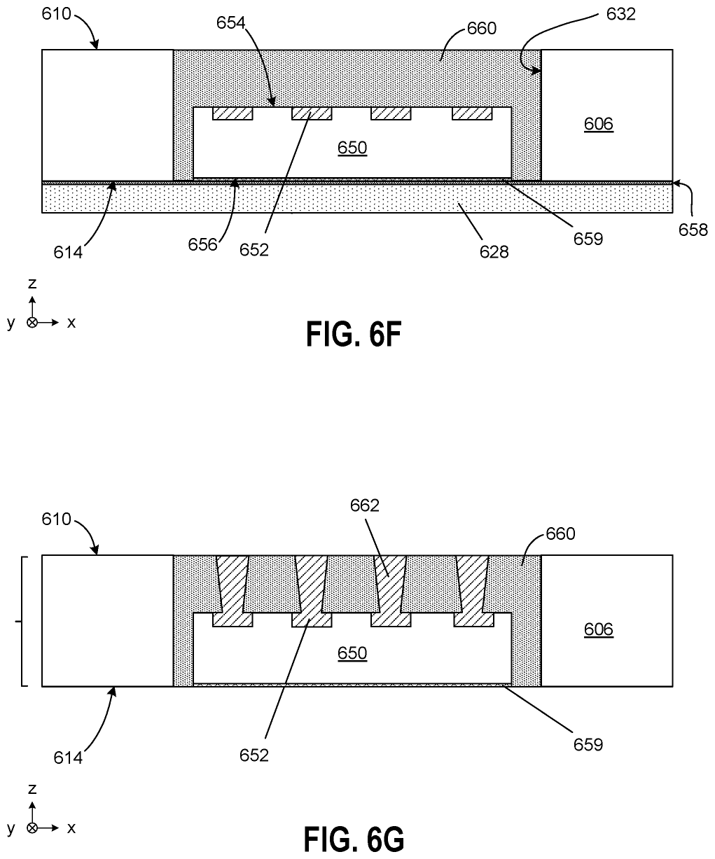

FIG. 6A is a cross-sectional view of an exemplary workpiece 600 comprising a substrate core 606. The substrate core 606 includes a first surface 610 and a second surface 614 opposite the first surface. First surface 610 may be referred to as a “front” or “front side” surface and second surface 614 may be referred to as a “back” or “back side” surface.

In some embodiments, the substrate core 606 comprises one or more an organic material or materials, e.g., epoxy. In embodiments in which the substrate core comprises organic material(s), the materials may include fillers, e.g., glass cloth or fibers. In some embodiments, the substrate core 606 comprises glass. In some embodiments, the substrate core 206 comprises silicon. The glass may comprise any of the materials described herein with respect to substrate core 206. In some embodiments, the substrate core may include both organic materials and glass. In some embodiments, substrate core 606 is comprised of the same material as substrate core 206.

In embodiments, one or more voltage regulation (VR) circuitry components may be disposed within the substrate core 606. The VR circuitry may be for providing power to one or more die coupled with an IC device package assembly. The components may include any suitable circuit component, such as resistors, inductors, capacitors, or transistors. As described herein, the z-height of a die containing a capacitor, e.g., a DTC, may be limited by a manufacturing process. In particular, the maximum z-height of the die containing a capacitor (or other discrete component) may be less than a thickness T1 of substrate core 606.

In embodiments, a thickness T10 of substrate core 606 may be greater than the z-height of a die comprising a capacitor. Substrate core 606 has a thickness T10 that may vary with implementation. In embodiments, thickness T10 is between 100 μm to 3000 μm.

Referring to FIG. 5, methods 501 continue at block 515 where a hole is formed in the substrate core. The hole may be formed in various ways using any process known to be suitable. In some embodiments, the hole may be formed using a mechanical cutting tool, such as a drill bit, router, fly cut tool, or laser drill. In embodiments in which the substrate core is glass, the hole may be formed using laser ablation or a glass etch process (laser-assisted, or otherwise). FIG. 6B is a cross-sectional view of the workpiece 600 after a hole 646 has been formed in the substrate core 606. The hole 646 extends from first surface 610 through the substrate core 606 to second surface 614 and has a depth equal to thickness T10. The hole 646 includes sidewalls 632.

Referring to FIG. 5, methods 501 continue at block 520 where the substrate core is attached to a carrier with a releasable bond film. The carrier is rigid to provide stability to the package during fabrication. The carrier may be of any suitable material, such as stainless steel, glass, silicon, fiber-glass reinforced epoxy, among others. The releasable bond film may include any suitable adhesive material that allows the carrier to be removed after processing through a suitable technique, such as exposure to high temperature, or laser light. FIG. 6C is a cross-sectional view of the workpiece 600 after the substrate core 606 has been attached to a carrier 628. Substrate core 606 may be attached at back side 614 to carrier 628 with a releasable bond film 658.

Referring to FIG. 5, methods 501 continue at block 525 where a first die 650 is placed in the hole and attached to the carrier. The first die may be placed in any suitable way known in the art, such as with a pick and place tool. The first die may be attached to the carrier with a die attach film. The first die may include conductive contacts at one or both sides of the die. In some embodiments, the first die may comprise one or more discrete circuit elements, such as capacitor, inductors, resistors, or transistors. In an embodiment, the first die 650 includes a DTC.

FIG. 6D illustrates a cross-sectional view of a first die 650 positioned to be placed in the hole in the substrate core. The first die 650 may have a z-height or thickness T11 that is less than the z-height or thickness T10 of substrate core 606. In some embodiments, first die 650 may have a thickness T11 of between about 100 μm to 1000 μm. The first die 650 includes a top side 654 and a bottom side 656 opposite to top side 654. The first die 650 includes conductive contacts 652 at top side 654.

FIG. 6E illustrates a cross-sectional view of the substrate core 606 after the first die 650 has been placed within hole 646 and attached to carrier 628. As illustrated, a die attach film 659 may be disposed between bottom side 656 and carrier 628. In some embodiments, the die attach film 659 may be an epoxy or an organic resin. In other embodiments, die attach film 659 and releasable bond film 658 may be the same material. In some embodiments, the thickness D4 of die attach film 659 may be between 2 and 50 μm.

The first die 650 may be nearer to the back surface 614 than to front surface 610. The substrate core has a first height, e.g., thickness T10, and the first die 650 has a second height, e.g., thickness T11. The first height is greater than the second height by a height difference. The height difference is the sum of D3 and D4. Distance D3 is the distance between die top side 654 and front side surface 610 of the substrate core 606. Distance D4 is the distance between the die bottom side 656 and back side surface 614 of substrate core 606. Distance D4 may be the thickness of die attach film 659. For example, for a first height of 1000 μm, a second height of 650 μm, a distance D3 of 350 μm, and a distance D4 of 50 μm, the height difference is 400 μm. The ratio of D3 to the height difference is 350/400 μm, which is 88% of height difference. In embodiments, distance D3 is equal to at least eighty percent (80%) of the height difference. In embodiments, distance D3 is equal to at least eighty five percent (85%) of the height difference.

Referring to FIG. 5, methods 501 continue at block 530 where the first die 650 is encapsulated with a dielectric material and the dielectric material is planarized, and the substrate core is removed from the carrier. FIG. 6F illustrates a cross-sectional view of the substrate core 606 after a dielectric material 660 has been deposited over the top side 654 of and along the sides of first die 650 between the first die and sidewalls 632. The dielectric material 660 may also cover portions of the carrier 628 between the first die and sidewalls 632. Although a single dielectric material 660 is shown, multiple dielectric material layers may be applied over first die 650. For example, a first conformal dielectric material layer may be deposited to contact a sidewall of first die 650 and a non-conformal, planarizing dielectric material layer may then be deposited over the conformal dielectric material layer. The dielectric material 660 may be applied, for example, with a spin-on technique or and/or a sol-gel technique to substantially cover first die 650. Dielectric material 660 may also be applied with lamination and slit coating methods. In various embodiments, dielectric material 660 can be any suitable material, such as an Ajinomoto Build-up Film (ABF) substrate, other dielectric/organic materials, resins, epoxies, polymer adhesives, silicones, acrylics, polyimides, cyanate esters, thermoplastics, and/or thermosets. In some embodiments, dielectric material 660 can be a mold or a photo imageable dielectric (PID).

FIG. 6F also illustrates the substrate core 606 after any needed planarizing has been performed on the dielectric material 660. For example, a grind and/or polish process may partially remove and/or planarize the dielectric material 660 to provide a flat surface in the same plane as front surface 610 of substrate 606.

Referring to FIG. 5, methods 501 continue at block 535 where conductive vias are formed through the dielectric material over the conductive contacts at the front side of the first die. In an alternative, the substrate core may be removed from the carrier at block 535 instead of block 530. Operations at block 535 include forming openings extending substantially vertically through the dielectric material, and depositing electrically conductive material in the openings. The openings may be formed using lithography and etching processes, or laser drilling, as known in the art. Conductive material, e.g., copper, may be deposited in the openings using electroplating methods, as know in the art. Operations at block 535 may also include treating the releasable bond film in a manner to cause it to lose its adhesive property, such as exposing it to heat or light from a laser. FIG. 6G illustrates a cross-sectional view of the substrate core 606 after conductive vias 662 have been formed through the dielectric material 660 and the substrate core has removed from carrier 628. The conductive vias 662 are coupled with conductive contacts 652 at the top side 654 of first die 650. The conductive vias 662 extend between conductive contacts 652 and front surface 610 of substrate 606.

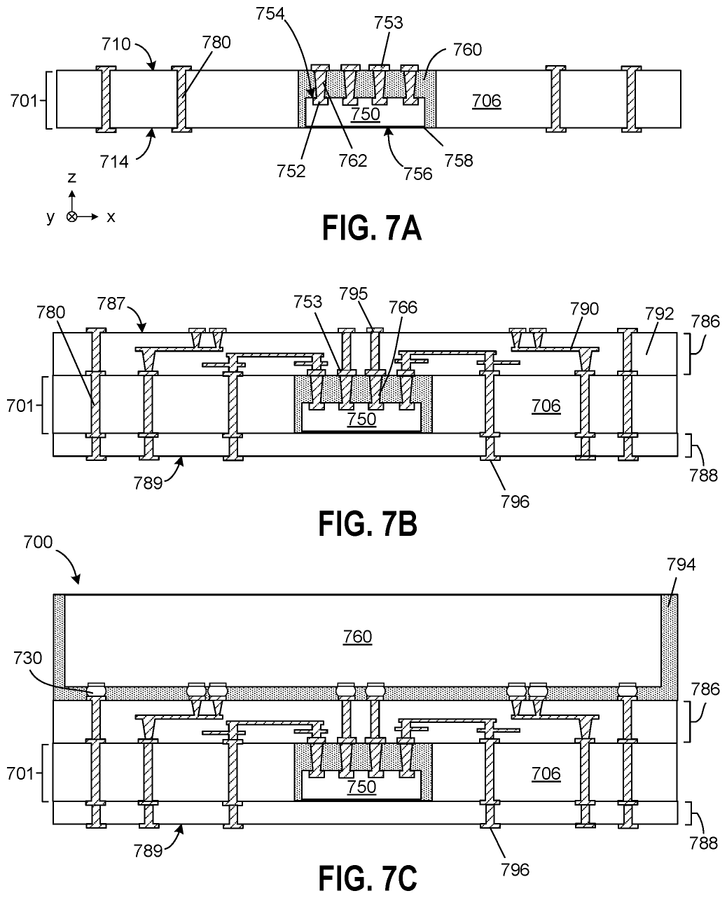

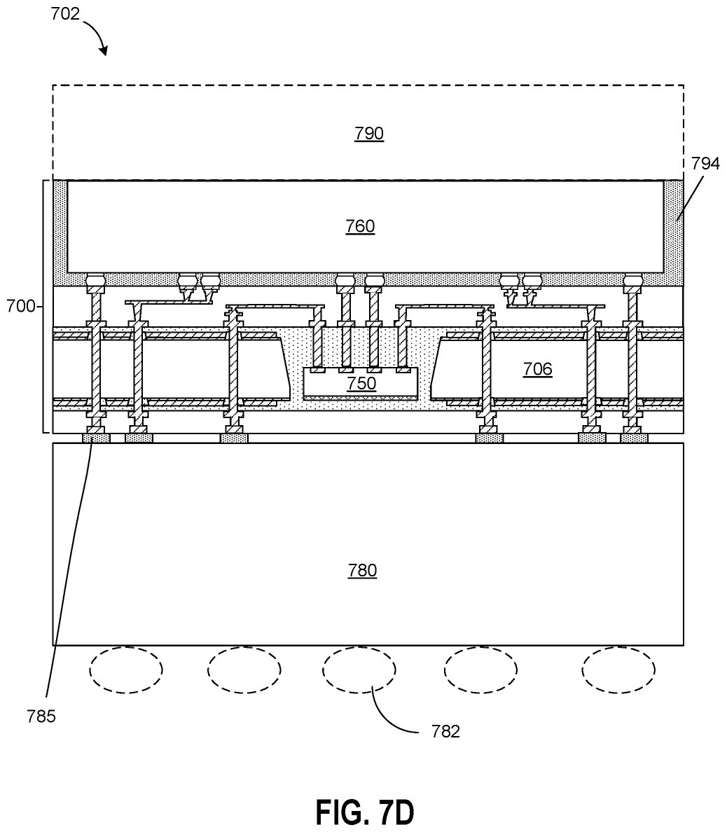

Referring again to FIG. 5, methods 501 continue at block 540 where an electrical routing structure is built up over at least one side of a substrate core prior to assembly with IC die. In addition, one or more integrated circuit (IC) die are assembled to the routing structure at block 540. FIG. 7A illustrates a cross-sectional view of a substrate core 706 that may be the same as or similar to substrate core 606. Substrate core 706 is used to illustrate embodiments that may not be readily seen in illustrations of substrate core 606. FIG. 7B illustrates a cross-sectional view of a substrate 701, which includes the substrate core 706, after an electrical routing structure has been built up over at least one side of the substrate. FIG. 7C illustrates a cross-sectional view of substrate 701 after an IC die is assembled to a routing structure.

Referring to FIG. 7A, in various embodiments, a substrate 701 includes substrate core 706 having a first (or front) surface 710 and a second (or back) surface 714. A first die 750 is within substrate core 706. First die 750 may be the same as or similar to first die 650. The first die 750 includes conductive contacts 752 at a top side 754, which are coupled with conductive vias 762. A dielectric material 751 may be over and around first die 750 and conductive vias 762. Dielectric material 751 may have dimensions, spatial relationships with other features of the substrate core 706, and a composition that is the same as or similar to the dielectric material 660. Conductive vias 762 extend through dielectric material 751 between conductive contacts 752 of the first die 750 and conductive contacts 753 at a top surface of the dielectric material 751. First die 750 includes a bottom side 756 opposite to top side 754. As illustrated, a bond film 758 may be disposed below bottom side 756 of first die 750. Bond film 758 may have a composition that is the same or similar to the composition of bond film 258. The substrate 701 includes through-substrate vias (TSV) 720 that extend through substrate core 706 between front surface 710 and back surface 714.

FIG. 7B is a cross-sectional view of substrate 701 after an electrical routing structure 786 has been built up over front surface 710 of the substrate. In addition, the figure shows an electrical routing structure 788 that has been built up over back surface 714. Electrical routing structure 786 includes a front surface 787 opposite a surface facing substrate 701. Electrical routing structure 788 includes a back surface 789 opposite a surface facing substrate 701. The electrical routing structures may be electrically coupled to the conductive vias 766, through substrate vias 720, and conductive contacts 753. The electrical routing structures may, for example, comprise one or more levels of metallization features embedded within any suitable dielectric material. The electrical routing structures may interconnect one or more IC die (including die 750 and IC die attached to the routing structure) to each other and/or couple the one or more of IC die to the conductive vias 766, TSVs 720, and conductive contacts 753.

In the example illustrated in FIG. 7B, a routing structure 786 has been built-up over front surface 710. Routing structures 786, 788 comprise one or more levels of RDL metallization features 790 embedded within one or more layers of dielectric material 792. The number of levels of RDL metallization features 790 in routing structures 786, 788 may be the same or different. The levels of RDL metallization features 790 RDL metallization features 790 may comprise one or more metals, with one example being predominantly copper. At least some of RDL metallization features 790 are to electrically couple first die 750 with conductive contacts 795 at front surface 787 of routing structure 786. Furthermore, at least some of RDL metallization features 790 are to electrically couple first die 750 with conductive contacts 796 at back surface 789 of routing structure 788. Routing structures 786, 788 further comprise metallization features 790 that are to interconnect multiple IC dies to conductive through substrate vias 720.

Depending on the embodiment, dielectric material 792 may be any of a molding compound, a spin-on material, or dry film laminate material, for example. Dielectric material 792 may be introduced wet/uncured into a cast and then dried/cured. Alternatively, dielectric material 792 may be introduced as a semi-cured dry film that is fully cured following its application to substrate 701.

The composition of dielectric material 792 may vary with implementation. In some advantageous embodiments, dielectric material 792 is an organic dielectric, such as, an epoxy resin, phenolic-glass, or a resinous film such as the GX-series films commercially available from Ajinomoto Fine-Techno Co., Inc. (ABF). In some embodiments, dielectric material 792 is a photo-imageable dielectrics (PID) or solder resist (SR). Dielectric material 792 may comprise epoxy resins (e.g., an acrylate of novolac such as epoxy phenol novolacs (EPN) or epoxy cresol novolacs (ECN)). In some specific examples, dielectric material 792 is a bisphenol-A epoxy resin, for example including epichlorohydrin. In other examples, dielectric material 792 includes aliphatic epoxy resin.

FIG. 7C illustrates a cross-sectional view of substrate 701 after an IC die is assembled to a routing structure 786. A package dielectric 794, such as a mold material, may surround sidewalls of IC die 760. While not shown in the figure, underfill, a non-conductive film, of a non-conductive paste may be disposed between IC die 760 and routing structures 786. The IC die may comprise any electrical circuitry, with one example being logic circuitry comprising logic gates. The IC die assembled may also comprise any photonic circuitry suitable for the detection, emission or processing (e.g., filtering, multiplexing and demultiplexing) of optical signals. While only one IC die is illustrated in the figure, two or more IC die may be assembled to a routing structure in other embodiments.

In the example illustrated in FIG. 7C, IC die 760 is assembled to interconnect interfaces within a top metallization level of routing structure 786 of an IC device package structure 700. IC die 760 may be directly bonded to routing structure 786, or, electrically coupled through intervening electrical interconnects 730, which may comprise solder of any suitable composition. In the example illustrated, IC die 760 is flip-chip attached with integrated circuitry within the die being proximal to front surface 787.

IC die 760 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, IC die 760 includes one or more banks of active repeater circuitry to improve multi-die interconnects (e.g., network-on-chip architectures). In other examples, IC die 760 includes clock generator circuitry or temperature sensing circuitry. In other examples, IC die 760 include logic circuitry that, along with other IC die implement multi-chiplet aggregated logic circuitry (e.g., mesh network-on-chip architectures). In some specific examples, IC die 760 includes microprocessor core circuitry, for example comprising one or more shift registers.

IC die 760 advantageously comprises field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 760 may include active devices other than FETs. For example, IC die 760 may include electronic memory structures, such as magnetic tunnel junctions (MTJs), capacitors, or the like.

IC die 760 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 760 may have a feature pitch ranging from 100 nm to several microns, for example.

Referring again to FIG. 5, where methods 501 complete at output 580 where the assembled device package structure is attached to any suitable host component. FIG. 7D illustrates an exemplary system 702 including one device package structure 700 attached to a host component 780 with interconnects 785, in accordance with some embodiments. In exemplary embodiments, interconnects 785 are solder (e.g., SAC) microbumps although other interconnect features are also possible. In some embodiments, host component 780 is predominantly silicon. Host component 780 may also comprise one or more alternative materials known to be suitable as interposers or package substrates (e.g., an epoxy preform, cored or coreless laminate board, etc.). Host component 780 may also include a printed circuit board (PCB). Host component 780 may include one or more metallized redistribution levels (not depicted) embedded within a dielectric material. Host component 780 may also include one or more IC die embedded therein.

Host component 780 may include interconnects 782 illustrated in dashed line.

Interconnect 782 may comprise any solder (ball, bump, etc.) suitable for a given host board architecture (e.g., surface mount FR4, etc.). Also illustrated in dashed line, one or more heat spreaders and/or heat sinks 798 may be further coupled to device package structure 700, which may be advantageous, for example, where IC die 760 comprises one or more CPU cores or other circuitry of similar power density. Any package dielectric 794, such as a mold material, may surround sidewalls of IC die 760. Although not illustrated, package dielectric 794 may be background so that heat spreader/sink 798 may be in closer contact with IC die 760.

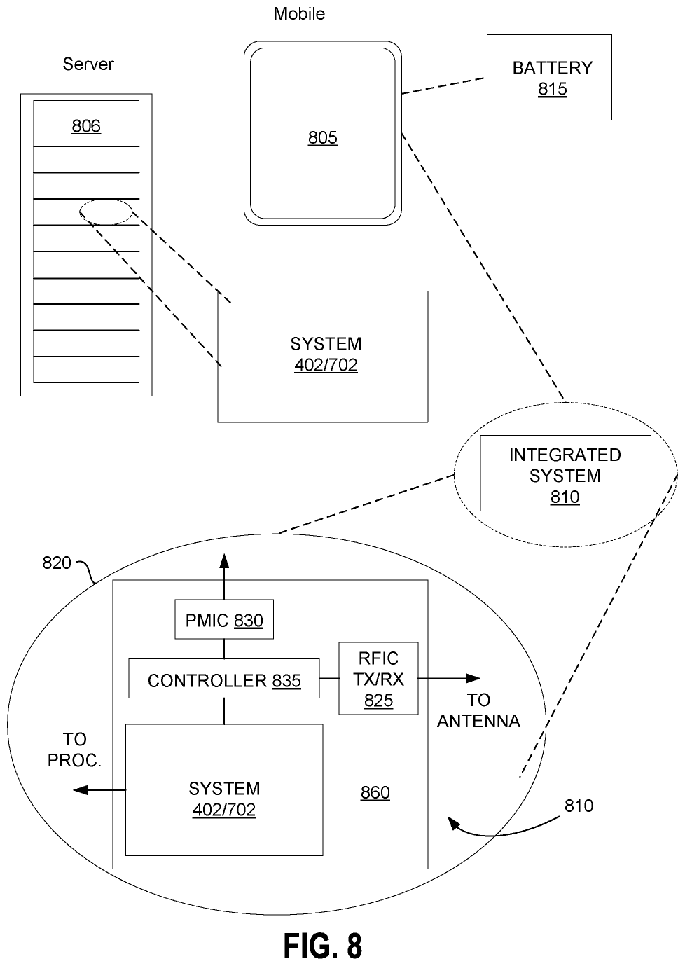

FIG. 8 illustrates a mobile computing platform and a data server machine employing one or more IC device package structures, for example as described elsewhere herein. For example, mobile computing platform 805 or server machine 806 may include IC device package structures illustrated in FIG. 4C and/or FIG. 7C, and/or one or more of the systems illustrated in FIG. 4D and/or FIG. 7D. Server machine 806 may be any commercial server, for example including any number of high-performance computing platforms disposed within a rack and networked together for electronic data processing, which in the exemplary embodiment includes an IC device package including a die within and near a back side of a substrate core, and conductive vias extending from a front side of the die to a surface of the substrate core, wherein the height of the die is less than the height of the substrate core, as described elsewhere herein. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), a chip-level or package-level integrated system 810, and a battery 815.

Whether disposed within the integrated system 810 illustrated in the expanded view 820, or as a stand-alone package within the server machine 806, the integrated system or server machine includes system 402 or system 702, wherein the system includes an IC device package including a die within and near a back side of a substrate core, and conductive vias extending from a front side of the die to a surface of the substrate core, wherein the height of the die is less than the height of the substrate core, as described elsewhere herein. For example, system 550 may comprise system 402 or system 702, which is described elsewhere herein. System 550 may be further coupled to a host substrate 860, along with, one or more of a power management integrated circuit (PMIC) 830, RF (wireless) integrated circuit (RFIC) 825 including a wideband RF (wireless) transmitter and/or receiver (TX/RX) (e.g., including a digital baseband and an analog front-end module further comprises a power amplifier on a transmit path and a low noise amplifier on a receive path), and a controller 835. PMIC 830 may perform battery power regulation, DC-to-DC conversion, etc., and so has an input coupled to battery 815 and with an output providing a current supply to other functional modules. As further illustrated, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

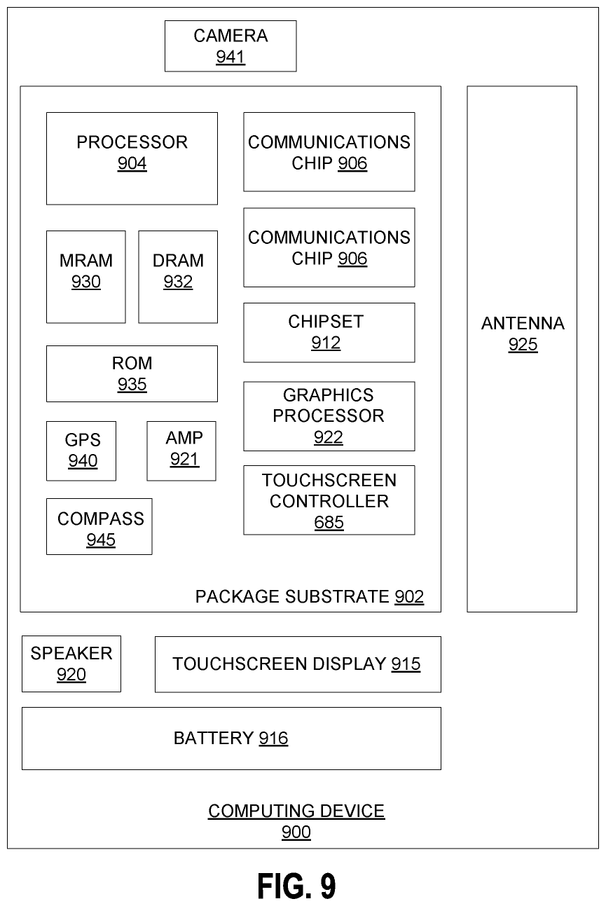

FIG. 9 is a functional block diagram of an electronic computing device 900, in accordance with an embodiment of the present invention. The computing device an IC device package including a die within and near a back side of a substrate core, and conductive vias extending from a front side of the die to a surface of the substrate core, wherein the height of the die is less than the height of the substrate core, as described herein. Device 900 further includes a package substrate 902 hosting a number of components, such as, but not limited to, a processor 904 (e.g., an applications processor). Processor 904 may be physically and/or electrically coupled to package substrate 902. In some examples, processor 904 is within system 402 or system 702, for example, as described elsewhere herein. Processor 904 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 906 may also be physically and/or electrically coupled to the package substrate 902. In further implementations, communication chips 906 may be part of processor 904. Depending on its applications, computing device 900 may include other components that may or may not be physically and electrically coupled to package substrate 902. These other components include, but are not limited to, volatile memory (e.g., DRAM 932), non-volatile memory (e.g., ROM 935), flash memory (e.g., NAND or NOR), magnetic memory (MRAM 930), a graphics processor 922, a digital signal processor, a crypto processor, a chipset 912, an antenna 925, touchscreen display 915, touchscreen controller 985, battery 916, audio codec, video codec, power amplifier 921, global positioning system (GPS) device 940, compass 945, accelerometer, gyroscope, speaker 920, camera 941, and mass storage device (such as hard disk drive, solid-state drive (SSD), compact disk (CD), digital versatile disk (DVD), and so forth), or the like.

Communication chips 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 906 may implement any of a number of wireless standards or protocols. As discussed, computing device 900 may include a plurality of communication chips 906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus, comprising: a substrate core comprising a first height between a first surface and a second surface opposite the first surface; a die within the substrate core comprising a second height between a first side and a second side opposite the first side, wherein the first height is greater than the second height; a plurality of conductive vias extending from a plurality of conductive contacts at the first side of the die to the first surface; and a material comprising a dielectric over the die and encapsulating the plurality of conductive vias.

Example 2: The apparatus of example 1, wherein the die comprises a deep trench capacitor.

Example 3: The apparatus of example 1 or example 2, wherein the plurality of conductive vias span a distance from the first side of the die to the first surface of the substrate core, the first height is greater than the second height by a height difference, and the distance is equal to at least eighty percent of the height difference.

Example 4: The apparatus of any of examples 1 through 3, wherein the second side of the die is spaced away from a plane of the second surface of the substrate core, further comprising a bond film in contact with the second side of the die, the bond film comprising a polymer adhesive.

Example 5: The apparatus of any of examples 1 through 4, wherein the material comprising a dielectric comprises a side that is substantially coplanar with the second surface of the substrate core.

Example 6: The apparatus of any of examples 1 through 4, wherein the second side of the die is substantially coplanar with the second surface of the substrate core.

Example 7: The apparatus of any of examples 1 through 7, wherein the die comprises a sidewall between the first side and the second side, and the material comprising a dielectric is between the sidewall and the substrate core.

Example 8: The apparatus of any of examples 1 through 7, wherein the substrate core comprises a third surface between the first surface and the second surface, and the third surface comprises: a first region comprising a first average surface roughness; a second region comprising a second average surface roughness; and wherein the second average surface roughness is less than the first average surface roughness.

Example 9: The apparatus of any of examples 1 through 8, wherein the first surface is in a first plane, the substrate core comprises a third surface between the first surface and the second surface, wherein the third surface is perpendicular to the first plane and comprises: a first region in a second plane, wherein an angle between the first plane and the second plane is a non-ninety-degree angle; and a second region substantially perpendicular to the first plane.

Example 10: The apparatus of any of examples 1 through 9, wherein the die is a first die, further comprising: an electrical routing structure on the first surface, the electrical routing structure comprising metallization features and an organic dielectric material; and a second die coupled to the electrical routing structure, wherein the plurality of conductive vias are coupled with the electrical routing structure to couple the first die with the second die.

Example 11: The apparatus of any of examples 1 through 10, wherein the substrate core comprises an organic material.

Example 12: The apparatus of any of examples 1 through 10, wherein the substrate core comprises a glass.

Example 13: A system, comprising: a substrate core comprising a first thickness between a front side surface and a back side surface opposite the front side surface; a die within the substrate core comprising a second thickness between a first side and a second side opposite the first side, wherein die comprises a deep trench capacitor, and the first thickness is greater than the second thickness by a thickness difference; a plurality of conductive vias extending from a plurality of conductive contacts at the first side of the die to the front side surface; and a second die electrically coupled to first metallization features in an electrical routing structure over the front side surface of the substrate core.

Example 14: The system of example 13, further comprising a material comprising a dielectric over the die and encapsulating the plurality of conductive vias.

Example 15: The system of example 13 or example 14, wherein the second side of the die is spaced away from a plane of the back side surface of the substrate core, further comprising a bond film in contact with the second side of the die.

Example 16: The system of any of examples 13 through 15, wherein the plurality of conductive vias span a distance from the first side of the die to the front side surface of the substrate core, the first thickness is greater than the second thickness by a thickness difference, and the distance is equal to at least eighty percent of the thickness difference.

Example 17: The system of example 16, further comprising a material comprising a dielectric over the die and encapsulating the plurality of conductive vias, wherein the material comprising a dielectric comprises a side that is substantially coplanar with the back side surface of the substrate core.

Example 18: A method comprising: receiving a workpiece comprising a substrate core, the substrate core comprising a first height between a first surface and a second surface opposite the first surface; placing a first die within a hole in the substrate core, the first die comprising a second height between a first side and a second side opposite the first side, wherein die comprises a deep trench capacitor, and the first height is greater than the second height; depositing a dielectric material over the first die; and forming a plurality of conductive vias extending a distance from a plurality of conductive contacts at the first side of the die to the first surface.

Example 19: The method of example 18, further comprising: building up, over the first surface of the substrate core, an electrical routing structure coupled to the plurality of conductive vias; and attaching a second die to the electrical routing structure.

Example 20: The method of example 17 or example 18, further comprising forming the hole through the substrate core, wherein the forming of the hole comprises: forming the hole to a first depth using a mechanical cutting tool; and forming the hole to a second depth using a laser, wherein the second depth is greater than the first depth.

It will be recognized that principles of the disclosure are not limited to the embodiments so described, but instead can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a substrate core comprising a first height between a first surface and a second surface opposite the first surface;
a die within the substrate core comprising a second height between a first side and a second side opposite the first side, wherein the first height is greater than the second height;
a plurality of conductive vias extending from a plurality of conductive contacts at the first side of the die to the first surface; and
a material comprising a dielectric over the die and encapsulating the plurality of conductive vias.

2. The apparatus of claim 1, wherein the die comprises a deep trench capacitor.

3. The apparatus of claim 1, wherein the plurality of conductive vias span a distance from the first side of the die to the first surface of the substrate core, the first height is greater than the second height by a height difference, and the distance is equal to at least eighty percent of the height difference.

4. The apparatus of claim 1, wherein the second side of the die is spaced away from a plane of the second surface of the substrate core, further comprising a bond film in contact with the second side of the die, the bond film comprising a polymer adhesive.

5. The apparatus of claim 1, wherein the material comprising a dielectric comprises a side that is substantially coplanar with the second surface of the substrate core.

6. The apparatus of claim 1, wherein the second side of the die is substantially coplanar with the second surface of the substrate core.

7. The apparatus of claim 1, wherein the die comprises a sidewall between the first side and the second side, and the material comprising a dielectric is between the sidewall and the substrate core.

8. The apparatus of claim 1, wherein the substrate core comprises a third surface between the first surface and the second surface, and the third surface comprises:
a first region comprising a first average surface roughness;
a second region comprising a second average surface roughness; and
wherein the second average surface roughness is less than the first average surface roughness.

9. The apparatus of claim 1, wherein the first surface is in a first plane, the substrate core comprises a third surface between the first surface and the second surface, wherein the third surface is perpendicular to the first plane and comprises:
a first region in a second plane, wherein an angle between the first plane and the second plane is a non-ninety-degree angle; and
a second region substantially perpendicular to the first plane.

10. The apparatus of claim 1, wherein the die is a first die, further comprising:
an electrical routing structure on the first surface, the electrical routing structure comprising metallization features and an organic dielectric material; and
a second die coupled to the electrical routing structure, wherein the plurality of conductive vias are coupled with the electrical routing structure to couple the first die with the second die.

11. The apparatus of claim 1, wherein the substrate core comprises an organic material.

12. The apparatus of claim 1, wherein the substrate core comprises a glass.

13. A system, comprising:
a substrate core comprising a first thickness between a front side surface and a back side surface opposite the front side surface;
a die within the substrate core comprising a second thickness between a first side and a second side opposite the first side, wherein die comprises a deep trench capacitor, and the first thickness is greater than the second thickness by a thickness difference;
a plurality of conductive vias extending from a plurality of conductive contacts at the first side of the die to the front side surface; and
a second die electrically coupled to first metallization features in an electrical routing structure over the front side surface of the substrate core.

14. The system of claim 13, further comprising a material comprising a dielectric over the die and encapsulating the plurality of conductive vias.

15. The system of claim 13, wherein the second side of the die is spaced away from a plane of the back side surface of the substrate core, further comprising a bond film in contact with the second side of the die.

16. The system of claim 13, wherein the plurality of conductive vias span a distance from the first side of the die to the front side surface of the substrate core, the first thickness is greater than the second thickness by a thickness difference, and the distance is equal to at least eighty percent of the thickness difference.

17. The system of claim 16, further comprising a material comprising a dielectric over the die and encapsulating the plurality of conductive vias, wherein the material comprising a dielectric comprises a side that is substantially coplanar with the back side surface of the substrate core.

18. A method comprising:
receiving a workpiece comprising a substrate core, the substrate core comprising a first height between a first surface and a second surface opposite the first surface;
placing a first die within a hole in the substrate core, the first die comprising a second height between a first side and a second side opposite the first side, wherein die comprises a deep trench capacitor, and the first height is greater than the second height;
depositing a dielectric material over the first die; and
forming a plurality of conductive vias extending a distance from a plurality of conductive contacts at the first side of the die to the first surface.

19. The method of claim 18, further comprising:
building up, over the first surface of the substrate core, an electrical routing structure coupled to the plurality of conductive vias; and
attaching a second die to the electrical routing structure.

20. The method of claim 18, further comprising forming the hole through the substrate core, wherein the forming of the hole comprises:
forming the hole to a first depth using a mechanical cutting tool; and
forming the hole to a second depth using a laser, wherein the second depth is greater than the first depth.
